(19) United States
(12) Patent Application Publication
(10) Pub. No.: US 2025/0231345 A1
(43) Pub. Date: Jul. 17, 2025

(54) PHOTONIC REGISTER CIRCUIT

(71) Applicant: Milkshake Technology Inc., Menlo Park, CA (US)

(72) Inventors: Bicky A. Marquez, Kingston (CA); Joshua S. J. Baxter, Ottawa (CA)

(21) Appl. No.: 18/411,931

(22) Filed: Jan. 12, 2024

(51) Int. Cl. G02B 6/293; H03K 3/42

(52) U.S. Cl. CPC G02B 6/29386; H03K 3/42

(57) ABSTRACT

A photonic circuit operating as a photonic register includes a first set of cascading photonic gates coupled to a second set of cascading photonic gates. The first set of cascading photonic gates generates, at a first output, a first intermediate output signal based on a first photonic input signal and a second photonic input signal, and generates, at a second output, a second intermediate output signal based on the second intermediate output signal and the second photonic input signal. The second set of cascading photonic gates generates, at a first output, a first photonic output signal based on the first intermediate output signal and a second photonic output signal that was generated at a second output. The second set of cascading photonic gates generates, at the second output, the second photonic output signal based on the first intermediate output signal and the first photonic output signal.

### TECHNICAL FIELD

The present disclosure generally relates to a processor architecture and, more specifically, to a photonic register circuit for a photonic processor.

### BACKGROUND

Photonic hardware is favorable for applications requiring high bandwidth, low latency, and low switching energy for signal processing, data communications, and information processing (i.e., computing systems and operations). Recent innovations in silicon photonic fabrication have enabled the on-chip implementation of photonic circuits. This has opened a low-cost, high-precision, and scalable avenue for the development of photonic computing. Advances in photonic computing have demonstrated suitability for applications requiring high-bandwidth parallel processing, especially neural networks, offering higher speed and less energy consumption than equivalent networks implemented in digital or analog electronics. Various components of photonic processors (e.g., memory, counters, registers, etc.) are based on photonic flip-flops, photonic registers, and photonic counters. Hence, it is desirable to design photonic flip-flops, photonic registers and photonic counters that are suitable to support ever increasing processing speeds in photonic computing.

### SUMMARY

Embodiments of the present disclosure are directed to the implementation of a photonic circuit that operates as a photonic D-type register. The photonic circuit may include a first set of one or more cascading photonic gates having a first set of one or more inputs and a first set of one or more outputs, a first input of the first set of one or more inputs configured to receive a first photonic input signal, and a second input of the first set of one or more inputs configured to receive a second photonic input signal. The first set of one or more cascading photonic gates is configured to generate, at a first output of the first set of one or more outputs, a first intermediate output signal based at least in part on the first photonic input signal and the second photonic input signal. The first set of one or more cascading photonic gates is further configured to generate, at a second output of the first set of one or more outputs, a second intermediate output signal based at least in part on the first intermediate output signal and the second photonic input signal. The photonic circuit may further include a second set of one or more cascading photonic gates having a second set of one or more inputs and a second set of one or more outputs, a first input of the second set of one or more inputs coupled to the second output of the first set of one or more outputs and configured to receive the second intermediate output signal, a second input of the second set of one or more inputs coupled to the first output of the first set of one or more outputs and configured to receive the first intermediate output signal. The second set of one or more cascading photonic gates is configured to generate, at a first output of the second set of one or more outputs, a first photonic output signal based at least in part on the second intermediate output signal and a second photonic output signal that was output by the second set of one or more cascading photonic gates at a second output of the second set of one or more outputs. The second set of one or more cascading photonic gates is further configured to generate, at the second output of the second set of one or more outputs, the second photonic output signal based at least in part on the first intermediate output signal and the first photonic output signal.

Embodiments of the present disclosure are further directed to a non-transitory computer-readable storage medium comprising stored instructions. The instructions, when executed by at least one processor, cause the at least one processor to execute operations. The operations are comprised to instruct a first set of one or more cascading photonic gates of a photonic circuit to receive a first photonic input signal at a first input of a first set of one or more inputs and to receive a second photonic input signal at a second input of the first set of one or more inputs; instruct the first set of one or more cascading photonic gates to generate, at a first output of a first set of one or more outputs, a first intermediate output signal based at least in part on the first photonic input signal and the second photonic input signal; instruct the first set of one or more cascading photonic gates to generate, at a second output of the first set of one or more outputs, a second intermediate output signal based at least in part on the first intermediate output signal and the second photonic input signal; instruct a second set of one or more cascading photonic gates of the photonic circuit to receive the second intermediate output signal at a first input of a second set of one or more inputs coupled to the second output of the first set of one or more outputs, and to receive the first intermediate output signal at a second input of the second set of one or more inputs coupled to the first output of the first set of one or more outputs; instruct the second set of one or more cascading photonic gates to generate, at a first output of a second set of one or more outputs, a first photonic output signal based at least in part on the second intermediate output signal and a second photonic output signal that was output by the second set of one or more cascading photonic gates at a second output of the second set of one or more outputs, and instruct the second set of one or more cascading photonic gates to generate, at the second output of the second set of one or more outputs, the second photonic output signal based at least in part on the first intermediate output signal and the first photonic output signal.

The non-transitory computer-readable storage medium can be a digital storage medium, an analog storage medium, an optical storage medium, some other type of storage medium, or some combination thereof. The at least one processor can be an optical processor, an electronic processor (e.g., central processing unit (CPU) processor, machine learning (ML) processor, graphics processing unit (GPU) processor), some other type of processor, or some combination thereof.

Embodiments of the present disclosure are further directed to a method for operating a photonic circuit as a photonic D-type register. The method comprises: receiving a first photonic input signal at a first input of a first set of one or more inputs of a first set of one or more cascading photonic gates of a photonic circuit and a second photonic input signal at a second input of the first set of one or more inputs; generating, by the first set of one or more cascading photonic gates, a first intermediate output signal at a first output of a first set of one or more outputs of the first set of one or more cascading photonic gates based at least in part on the first photonic input signal and the second photonic input signal; generating, by the first set of one or more cascading photonic gates, a second intermediate output signal at a second output of the first set of one or more outputs based at least in part on the first intermediate output signal and the second photonic input signal; receiving the second intermediate output signal at a first input of a second set of one or more inputs of a second set of one or more cascading photonic gates and the first intermediate output signal at a second input of the second set of one or more inputs coupled to the first output of the first set of one or more outputs; generating, by the second set of one or more cascading photonic gates, a first photonic output signal at a first output of a second set of one or more outputs of the second set of one or more cascading photonic gates based at least in part on the second intermediate output signal and a second photonic output signal that was output by the second set of one or more cascading photonic gates at a second output of the second set of one or more outputs; and generating, by the second set of one or more cascading photonic gates, the second photonic output signal at the second output of the second set of one or more outputs based at least in part on the first intermediate output signal and the first photonic output signal.

### BRIEF DESCRIPTION OF THE DRAWINGS

Figure (FIG. 1 illustrates an example photonic system with a photonic circuit that operates as a photonic set-reset (SR) flip-flop, in accordance with some embodiments.

FIG. 2 illustrates an example photonic system with a photonic circuit that operates as a photonic NAND-based pre-flip-flop gate, in accordance with some embodiments.

FIG. 3 illustrates an example photonic system with a photonic circuit that operates as a photonic D-type register, in accordance with some embodiments.

FIG. 4 illustrates an example photonic counter circuit, in accordance with some embodiments.

FIG. 5 illustrates an example graph of photonic bit signals generated by the photonic counter circuit in FIG. 4, in accordance with some embodiments.

FIG. 6 illustrates an example photonic D-type flip-flop of the photonic counter circuit in FIG. 4, in accordance with some embodiments.

FIG. 7 is a flowchart illustrating an example method for operating a photonic circuit as a photonic SR flip-flop, in accordance with some embodiments.

FIG. 8 is a flowchart illustrating an example method for operating a photonic circuit as a photonic NAND-based pre-flip-flop gate, in accordance with some embodiments.

FIG. 9 is a flowchart illustrating an example method for operating a photonic circuit as a photonic D-type register, in accordance with some embodiments.

FIG. 10 is a flowchart illustrating an example method for operating a photonic counter circuit, in accordance with some embodiments.

The figures depict embodiments of the present disclosure for purposes of illustration only. One skilled in the art will readily recognize from the following description that alternative embodiments of the structures and methods illustrated herein can be employed without departing from the principles or benefits touted by the disclosure described herein.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that can be employed without departing from the principles of what is claimed.

Reference will now be made in detail to several embodiments, examples of which are illustrated in the accompanying figures. It is noted that wherever practicable, similar or like reference numbers can be used in the figures and can indicate similar or like functionality. The figures depict embodiments of the disclosed system (or method) for illustration only. One skilled in the art will readily recognize from the following description that alternative embodiments of the structures and methods illustrated herein can be employed without departing from the principles described herein.

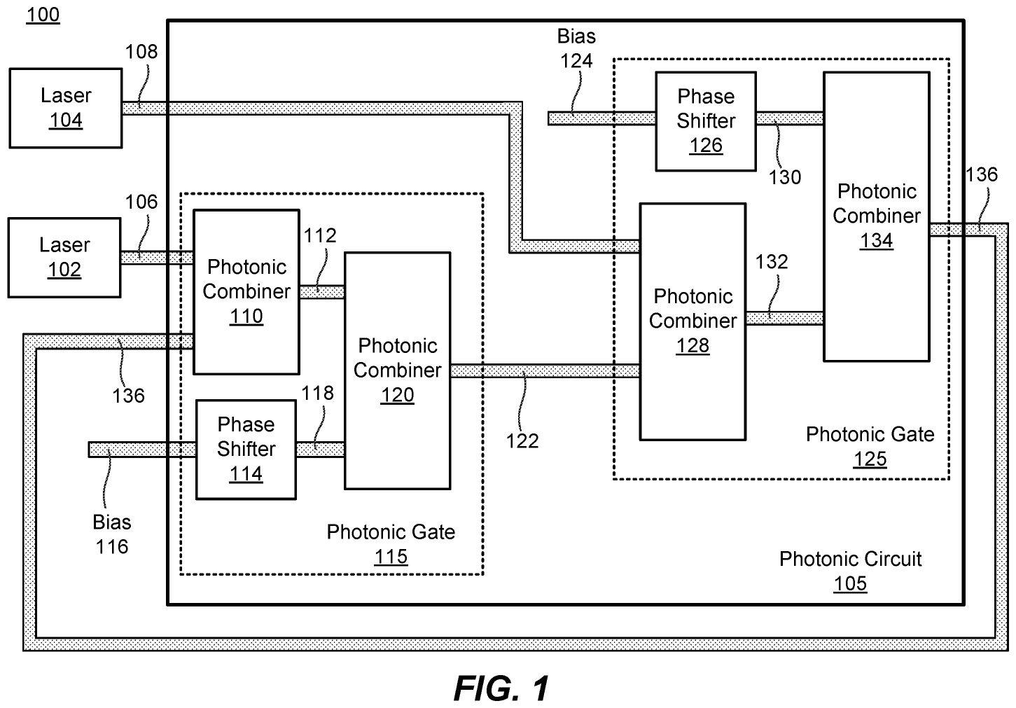

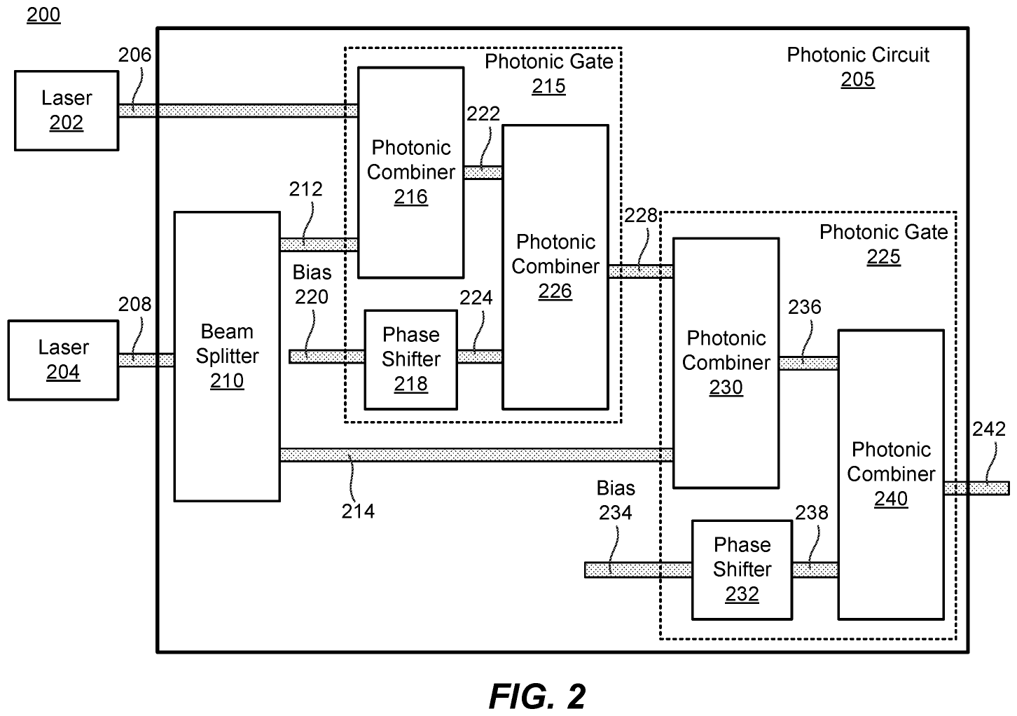

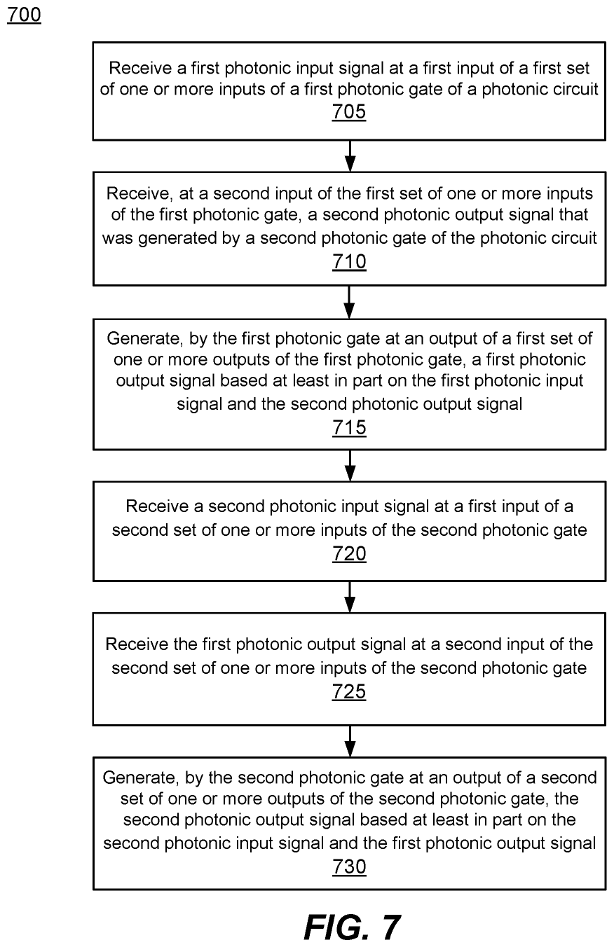

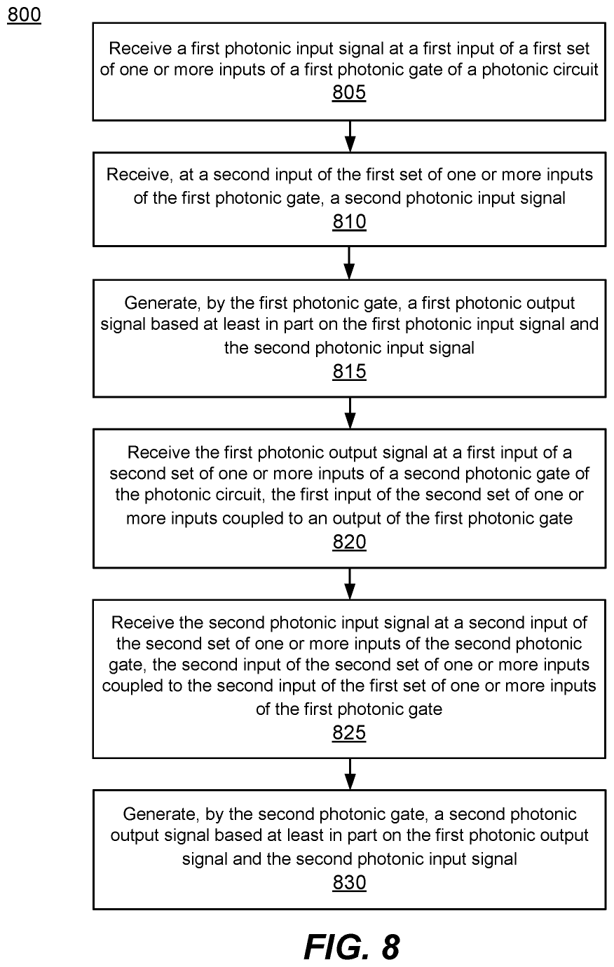

Embodiments of the present disclosure are directed to the implementation of photonic circuits that operate as multi-channel (e.g., one or more channels) photonic flip-flops and photonic pre-flip-flop gates. A multi-channel photonic flip-flop presented herein is implemented as a cascaded connection of a pair of photonic NAND gates with feedback to operate as a photonic set-reset (SR) flip-flop. A multi-channel photonic pre-flip-flop gate presented herein is implemented as a cascaded connection of a pair of photonic NAND gates without feedback to operate as a photonic NAND-based pre-flip-flop gate. Each photonic NAND gate in a photonic SR flip-flop is implemented using two or more photonic combiners and one or more phase shifters, any other combination of photonic components that operate as a photonic NAND gate, or is autonomously designed using inverse design or any other optimization techniques for photonics design. Some embodiments of the photonic NAND gates can be cascaded without any amplitude thresholders. An amplitude of the bias signal is determined such that the cascaded connection of photonic NAND gates produces a correct multi-channel truth table. Light signals of one or more wavelengths can be multiplexed and simultaneously input into the SR photonic flip-flop and the photonic pre-flip-flop gate as multiple independent input channels for producing multiple output channels in parallel. The SR photonic flip-flops and the photonic pre-flip-flop gates presented in this disclosure can be used for building photonic registers in photonic processors. In some embodiments, to avoid amplitude attenuation and/or phase errors, the photonic pre-flip-flop gate and/or the photonic SR flip-flop are implemented to include one or more nonlinear optical or electro-optical components (e.g., one or more photonic amplitude thresholders). The photonic flip-flop may require one or more thresholders (e.g., electro-optical thresholders, optical thresholders, saturable optical absorbers, semiconductor optical amplifiers, etc.). In one or more embodiments, the photonic pre-flip-flop gate may not require any thresholders. Details about structures and operations of the photonic flip-flops and the pre-flip-flop gates (e.g., photonic SR flip-flop and photonic NAND-based pre-flip-flop gate) are described in relation to FIG. 1, FIG. 2, FIG. 7, and FIG. 8.

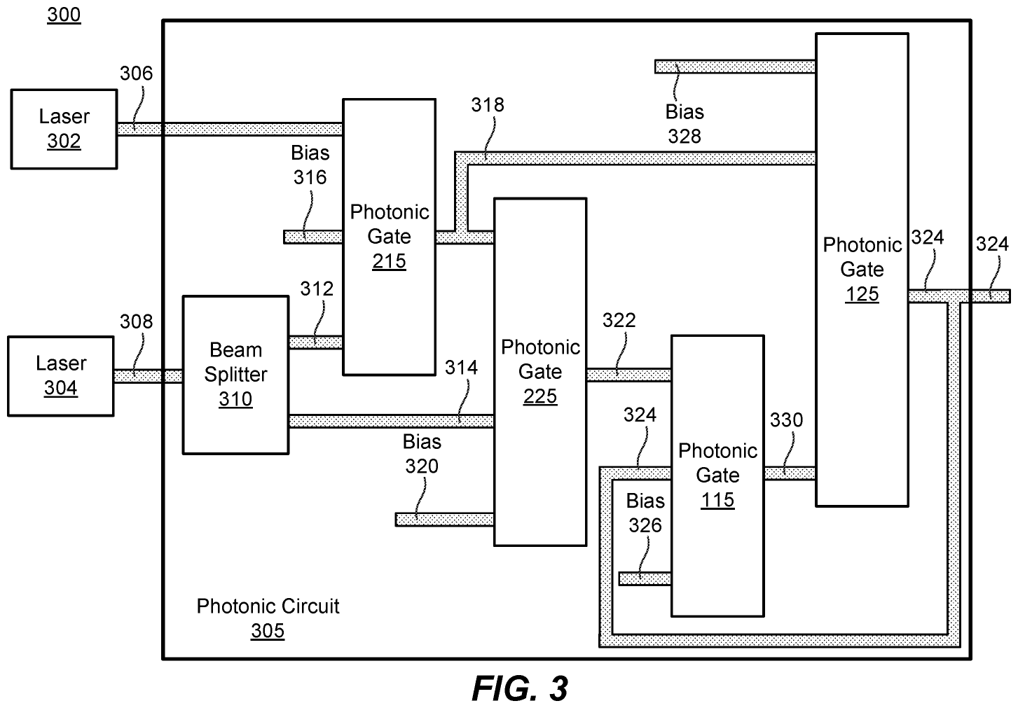

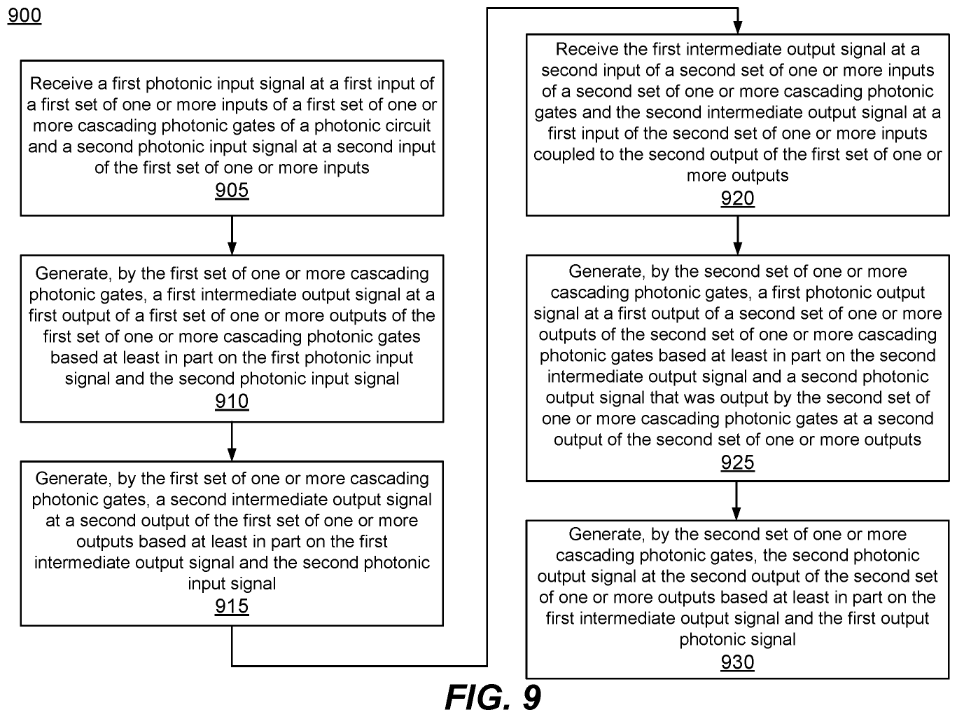

Embodiments of the present disclosure are further directed to the implementation of a photonic circuit that operates as a photonic register. A multi-channel photonic D-type register (or photonic D-type flip-flop) is implemented as a cascaded connection of a photonic NAND-based pre-flip-flop gate and a photonic SR flip-flop. The photonic NAND-based pre-flip-flop gate in the photonic D-type register is implemented as a cascaded connection of a pair of photonic NAND gates. The photonic SR flip-flop in the photonic D-type register is implemented as a cascaded connection of a pair of photonic NAND gates with feedback. Each photonic NAND gate in the photonic D-type register is implemented using two or more photonic combiners and one or more phase shifters, any other combination of photonic components that operate as a photonic NAND gate, or is autonomously designed using inverse design or any other optimization techniques for photonics design. Light signals of one or more wavelengths can be multiplexed and stored in parallel in the photonic D-type register as multiple input channels. In some embodiments, to avoid amplitude attenuation and/or phase errors, the photonic pre-flip-flop gate and the photonic SR flip-flop within the photonic D-type register are implemented to include one or more nonlinear or electro-optical components (e.g., one or more photonic amplitude thresholders). Details about a structure and operation of the photonic register circuit (e.g., photonic D-type register) are described in relation to FIG. 3 and FIG. 9.

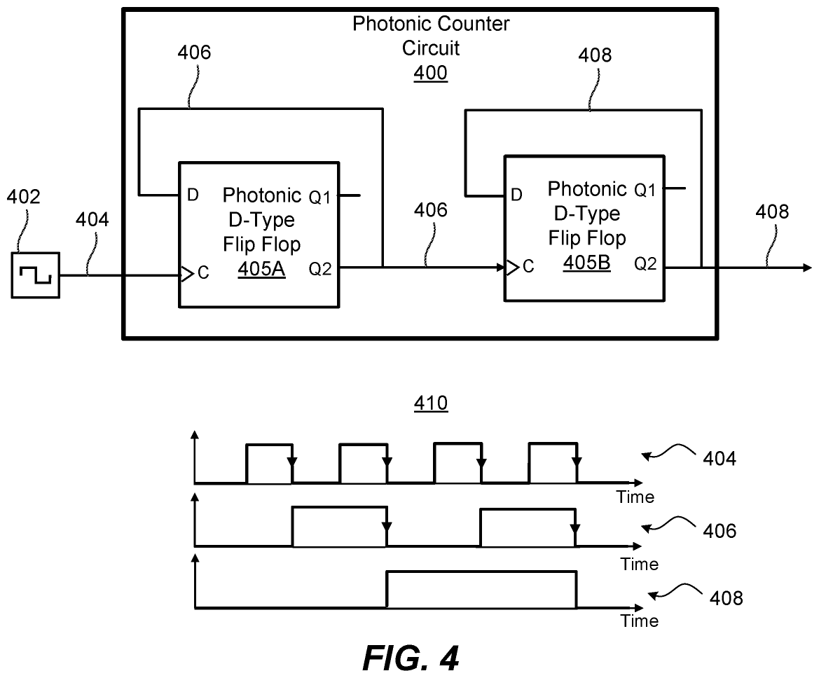

Embodiments of the present disclosure are further directed to the implementation of a photonic counter circuit for use in photonic processors. The photonic counter circuit is implemented as a cascaded connection of multiple (e.g., two) photonic D-type flip-flops (i.e., photonic D-type registers) with a beam splitter and feedback. Each photonic D-type flip-flop of the photonic counter circuit is implemented as a cascaded connection of a photonic pre-flip-flop gate and a photonic SR flip-flop. Both the photonic pre-flip-flop gate and the photonic SR flip-flop in the photonic D-type flip-flop are implemented as a cascaded connection of a pair of photonic NAND gates with feedback (for the photonic SR flip-flop) or without feedback (for the photonic pre-flip-flop gate). Each photonic NAND gate in the photonic SR flip-flop (and in the photonic pre-flip-flop gate) is implemented using two or more photonic combiners and one or more phase shifters, any other combination of photonic components that operate as a photonic NAND gate, or is autonomously designed using inverse design or any other optimization techniques for photonic design. In some embodiments, to avoid amplitude attenuation and/or phase errors, a photonic D-type flip-flop including the constituent photonic pre-flip-flop gate and photonic SR flip-flop within the photonic counter circuit is implemented to include one or more nonlinear optical or electro-optical components (e.g., one or more photonic amplitude thresholders). Details about a structure and operation of the photonic counter circuit are described in relation to FIGS. 4-6 and FIG. 10.

### Photonic Set-Reset Flip-Flop

FIG. 1 illustrates an example photonic system 100 with a photonic circuit 105 that operates as a photonic set-reset (SR) flip-flop, in accordance with some embodiments. In addition to the photonic circuit 105, the photonic system 100 may include a laser 102 coupled to a first input port of the photonic circuit 105 and a laser 104 coupled to a second input port of the photonic circuit 105. A third input port (e.g., a bias signal port) of the photonic circuit 105 may be coupled to a signal line for a bias signal source. The laser 102 may generate a photonic input signal 106 injected into the first input port of the photonic circuit 105, and the laser 104 may generate a photonic input signal 108 injected into the second input port of the photonic circuit 105.

The photonic circuit 105 may generate photonic output signals 122 and 136 based on the photonic input signals 106 and 108 while operating as the photonic SR flip-flop. The photonic circuit 105 may include a photonic combiner 110, a phase shifter 114, a photonic combiner 120, a phase shifter 126, a photonic combiner 128 and a photonic combiner 134. A first input port of the photonic combiner 110 may be coupled to an output port of the laser 102, and a second input port of the photonic combiner 110 may be coupled to an output port of the photonic combiner 134. An output port of the photonic combiner 110 may be coupled to a first input port of the photonic combiner 120, and an output port of the phase shifter 114 may be coupled to a second input port of the photonic combiner 120. An output port of the photonic combiner 120 may be coupled to a second input port of the photonic combiner 128, and an output port of the laser 104 may be coupled to a first input port of the photonic combiner 128. An output port of the photonic combiner 128 may be coupled to a second input port of the photonic combiner 134, and an output port of the phase shifter 126 may be coupled to a first input port of the photonic combiner 134. It is noted that the input/output ports may be coupled through signal transmission lines (or signal lines). The photonic combiner 110, the phase shifter 114 and the photonic combiner 120 may form a photonic gate 115; and the phase shifter 126, the photonic combiner 128 and the photonic combiner 134 may form a photonic gate 125. Hence, the photonic circuit 105 may include a cascading connection of the pair of photonic gates 115 and 125. The photonic circuit 105 may include fewer or additional components not shown in FIG. 1, such as, but not limited to, additional photonic combiners, beam splitters, additional phase shifters, linear photonic amplifiers, photonic attenuators, and/or photonic amplitude thresholders. Furthermore, the constituent circuits of the photonic circuit 105 that may act as photonic NAND gates (e.g., the photonic gates 115 and 125) may be replaced by alternative photonic circuits with substantially same operations, inverse-designed gates, or gates designed using other optimization techniques for photonic design.

The laser 102 may generate and emit the photonic input signal 106 of one or more wavelengths (or modes). Alternatively, the photonic input signal 106 may be generated by another photonic circuit having an output port coupled to the first input port of the photonic circuit 105. The photonic input signal 106 may be a light signal of corresponding input amplitudes (that each corresponds to logical “1” or logical “0”), corresponding input phases and/or corresponding input modes (i.e., input light spatial distribution and/or input wavelengths) provided at the output port of the laser 102 and injected into the first input port of the photonic circuit 105, i.e., into the first input port of the photonic combiner 110. The laser 102 may include one or more laser emitters, each laser emitter being configured to generate and emit the photonic input signal 106 of a respective wavelength. The one or more laser emitters of the laser 102 may be instructed (i.e., triggered) by at least one processor (e.g., optical processor, electronic processor, electro-optical processor, etc.) coupled to the one or more laser emitters to generate the photonic input signal 106 of one or more specific wavelengths. The output port of the laser 102 may represent, e.g., a set of one or more waveguides, a set of one or more waveguide polarizations, a set of one or more waveguide modes, a set of one or more light wavelengths, a set of one or more signals radiated by the laser 102, etc.

The laser 104 may generate and emit the photonic input signal 108 of one or more wavelengths (or modes). Alternatively, the photonic input signal 108 may be generated by another photonic circuit having an output port coupled to the second input port of the photonic circuit 105. The photonic input signal 108 may be a light signal of corresponding input amplitudes (that each corresponds to logical “1” or logical “0”), corresponding input phases provided at the output port of the laser 104 and injected into the second input port of the photonic circuit 105, i.e., into the first input port of the photonic combiner 128. The laser 104 may include one or more laser emitters, each laser emitter being configured to generate and emit the photonic input signal 108 of a respective wavelength. The one or more laser emitters of the laser 104 may be instructed (i.e., triggered) by at least one processor (e.g., optical processor, electronic processor, electro-optical processor, etc.) coupled to the one or more laser emitters to generate the photonic input signal 108 of one or more specific wavelengths. The output port of the laser 104 may represent, e.g., a set of one or more waveguides, a set of one or more waveguide polarizations, a set of one or more waveguide modes, a set of one or more light wavelengths, a set of one or more signals radiated by the laser 104, etc.

The photonic combiner 110 may receive, at its first input port, the photonic input signal 106 generated by the laser 102. The photonic combiner 110 may further receive, at its second input port, the photonic output signal 136 generated by the photonic combiner 134. The set of input ports of the photonic combiner 110 may represent, e.g., a set of waveguides, a set of waveguide polarizations, a set of waveguide modes, a set of light wavelengths, etc. The first input port of the photonic combiner 110 may also represent the first input port of the photonic circuit 105, whereas the second input port of the photonic combiner 110 may represent a feedback port of the photonic circuit 105 for feeding the photonic output signal 136 back to the photonic circuit 105. The photonic combiner 110 may generate a photonic signal 112 by combining the photonic input signal 106 and the photonic output signal 136. The photonic signal 112 may be output at an output port of the photonic combiner 110. The output port of the photonic combiner 110 may represent, e.g., a waveguide, a waveguide polarization, a waveguide mode, a light wavelength, a signal radiated by the photonic combiner 110, etc. The photonic signal 112 generated by the photonic combiner 110 may be passed to the photonic combiner 120.

The phase shifter 114 may receive a bias signal 116 at an input port of the phase shifter 114. The input port of the phase shifter 114 may represent, e.g., a waveguide, a waveguide polarization, a waveguide mode, a light wavelength, etc. The input port of the phase shifter 114 may also represent the third input port of the photonic circuit 105. The bias signal 116 that is input to the phase shifter 116 is a light signal of a defined amplitude level that is constant over time. The bias signal 116 may be generated by, e.g., a photonic local source coupled to the input port of the phase shifter 114 (not shown in FIG. 1). The phase shifter 114 is a linear photonic component that generates a photonic signal 118 by shifting a phase of the received bias signal 116. For example, the phase shifter 114 may apply a phase shift of x radians to the bias signal 116, i.e., the photonic signal 118 may represent an inverted version of the bias signal 116. The photonic signal 118 may be output at an output port of the phase shifter 114. The output port of the phase shifter 114 may represent, e.g., a waveguide, a waveguide polarization, a waveguide mode, a light wavelength, a signal radiated by the phase shifter 114, etc. The photonic signal 118 generated by the phase shifter 114 may be passed to the photonic combiner 120.

The photonic combiner 120 may receive, at its first input port, the photonic signal 112 generated by the photonic combiner 110. The photonic combiner 120 may further receive, at its second input port, the photonic signal 118 generated by the phase shifter 114. The set of input ports of the photonic combiner 120 may represent, e.g., a set of waveguides, a set of waveguide polarizations, a set of waveguide modes, a set of light wavelengths, etc. The photonic combiner 120 may generate the photonic output signal 122 by combining the photonic signal 112 and the photonic signal 118. Note that the phase shifter 114 and the photonic combiner 120 may effectively subtract the bias signal 116 from the photonic signal 112 to generate the photonic output signal 122. Note also that the photonic combiner 110, the phase shifter 114 and the photonic combiner 120 form the photonic gate 115 that operates as a linear NAND photonic logic gate. The photonic output signal 122 may be output at an output port of the photonic combiner 120. The output port of the photonic combiner 120 may represent, e.g., a waveguide, a waveguide polarization, a waveguide mode, a light wavelength, a signal radiated by the photonic combiner 120, etc. The output port of the photonic combiner 120 may also represent a first output port of the photonic circuit 105. The photonic output signal 122 generated by the photonic combiner 120 may be passed to the photonic combiner 128.

The phase shifter 126 may receive a bias signal 124 at an input port of the phase shifter 126. The input port of the phase shifter 126 may represent, e.g., a waveguide, a waveguide polarization, a waveguide mode, a light wavelength, etc. The bias signal 124 that is input to the phase shifter 126 is a light signal of a defined amplitude level that is constant over time. The bias signal 124 may be generated by, e.g., a photonic local source coupled to the input port of the phase shifter 126 (not shown in FIG. 1). The phase shifter 126 is a linear photonic component that generates a photonic signal 130 by shifting a phase of the received bias signal 124. For example, the phase shifter 126 may apply a phase shift of π radians to the bias signal 124, i.e., the photonic signal 130 may represent an inverted version of the bias signal 124. The photonic signal 130 may be output at an output port of the phase shifter 126. The output port of the phase shifter 126 may represent, e.g., a waveguide, a waveguide polarization, a waveguide mode, a light wavelength, a signal radiated by the phase shifter 126, etc. The photonic signal 130 generated by the phase shifter 126 may be passed to the photonic combiner 134.

The photonic combiner 128 may receive, at its first input port, the photonic input signal 108 generated by the laser 104. The photonic combiner 128 may further receive, at its second input port, the photonic output signal 122 generated by the photonic combiner 120. The set of input ports of the photonic combiner 128 may represent, e.g., a set of waveguides, a set of waveguide polarizations, a set of waveguide modes, a set of light wavelengths, etc. The first input port of the photonic combiner 128 may also represent the second input port of the photonic circuit 105. The photonic combiner 128 may generate a photonic signal 132 by combining the photonic input signal 108 and the photonic output signal 122. The photonic signal 132 may be output at an output port of the photonic combiner 128. The output port of the photonic combiner 128 may represent, e.g., a waveguide, a waveguide polarization, a waveguide mode, a light wavelength, a signal radiated by the photonic combiner 128, etc. The photonic signal 132 generated by the photonic combiner 128 may be passed to the photonic combiner 134.

The photonic combiner 134 may receive, at its first input port, the photonic signal 130 generated by the phase shifter 126. The photonic combiner 134 may further receive, at its second input port, the photonic signal 132 generated by the photonic combiner 128. The set of input ports of the photonic combiner 134 may represent, e.g., a set of waveguides, a set of waveguide polarizations, a set of waveguide modes, a set of light wavelengths, etc. The photonic combiner 134 may generate the photonic output signal 136 by combining the photonic signal 130 and the photonic signal 132. Note that the phase shifter 126 and the photonic combiner 134 may effectively subtract the bias signal 124 from the photonic signal 132 to generate the photonic output signal 136. Note also that the phase shifter 126, the photonic combiner 128 and the photonic combiner 134 form the photonic gate 125 that operates as a linear NAND photonic logic gate. The photonic output signal 136 may be output at an output port of the photonic combiner 134. The output port of the photonic combiner 134 may represent, e.g., a waveguide, a waveguide polarization, a waveguide mode, a light wavelength, a signal radiated by the photonic combiner 134, etc. The output port of the photonic combiner 134 may also represent a second output port of the photonic circuit 105. The photonic output signal 134 generated by the photonic combiner 134 may be fed back to the photonic combiner 110.

Note that the photonic circuit 105 effectively operates as a photonic SR flip-flop, where the photonic input signal 106 corresponds to the “S” (or “set”) input of the photonic SR flip-flop, the photonic input signal 108 corresponds to the “R” (or “reset”) input of the photonic SR flip-flop, the photonic output signal 122 corresponds to the “Q1” output of the photonic SR flip-flop, and the photonic output signal 136 corresponds to the “Q2” output of the photonic SR flip-flop. The photonic circuit 105 thus satisfies the truth table of the SR flip-flop: (1) when amplitudes of the photonic input signals 106, 108 corresponds to logical “0s”, amplitudes of the photonic output signals 122, 136 corresponds to logical “1s”; (2) when amplitudes of the photonic input signals 106, 108 corresponds to logical “0” and “1” respectively, amplitudes of the photonic output signals 122, 136 corresponds to logical “1” and logical “0” respectively; (3) when amplitudes of the photonic input signals 106, 108 corresponds to logical “1” and “0” respectively, amplitudes of the photonic output signals 122, 136 corresponds to logical “0” and logical “1” respectively; and (4) when amplitudes of the photonic input signals 106, 108 corresponds to logical “1s”, amplitudes of the photonic output signals 122, 136 correspond to logical “1” and logical “0” respectively, or to logical “0” and logical “1” respectively, depending on the previous output state. The photonic circuit 105 may satisfy the truth table of the SR flip-flop for a set of one or more wavelengths of the photonic input signals 106, 108 that correspond to the same set of wavelengths of the photonic output signals 122, 136.

### Photonic NAND-Based Pre-Flip-Flop Gate

FIG. 2 illustrates an example photonic system 200 with a photonic circuit 205 that operates as a photonic NAND-based pre-flip-flop gate, in accordance with some embodiments. In addition to the photonic circuit 205, the photonic system 200 may include a laser 202 coupled to a first input port of the photonic circuit 205 and a laser 204 coupled to a second input port of the photonic circuit 205. Other input ports of the photonic circuit 205 may be bias signal ports, each coupled to a respective signal line for a bias signal source. The laser 202 may generate a photonic input signal 206 injected into the first input port of the photonic circuit 205, and the laser 204 may generate a photonic input signal 208 injected into the second input port of the photonic circuit 205.

The photonic circuit 205 may generate photonic output signals 228 and 242 based on the photonic input signals 206 and 208 while operating as the photonic NAND-based pre-flip-flop gate. The photonic circuit 205 may include a beam splitter 210, a first photonic combiner 216 of a first photonic gate 215, a phase shifter 218 of the first photonic gate 215, a second photonic combiner 226 of the first photonic gate 215, a first photonic combiner 230 of a second photonic gate 225, a phase shifter 232 of the second photonic gate 225, and a second photonic combiner 240 of the second photonic gate 225. An input port of the beam splitter 210 may be coupled to an output port of the laser 204, a first output port of the beam splitter 210 may be coupled to a second input port of the photonic combiner 216, and a second output port of the beam splitter 210 may be coupled to a second input port of the photonic combiner 230. A first input port of the photonic combiner 216 may be coupled to an output port of the laser 202, and an output port of the photonic combiner 216 may be coupled to a first input port of the photonic combiner 226. A second input port of the photonic combiner 226 may be coupled to an output port of the phase shifter 218, and an output port of the photonic combiner 226 may be coupled to a first input port of the photonic combiner 230. An output port of the photonic combiner 230 may be coupled to a first input port of the photonic combiner 240, and an output port of the phase shifter 232 may be coupled to a second input port of the photonic combiner 240. It is noted that the input/output ports may be coupled through signal transmission lines (or signal lines). The photonic combiner 216, the phase shifter 218 and the photonic combiner 226 may form the photonic gate 215; and the photonic combiner 230, the phase shifter 232 and the photonic combiner 240 may form the photonic gate 225. Hence, the photonic circuit 205 may include a cascading connection of the pair of photonic gates 215 and 225. The photonic circuit 205 may include fewer or additional components not shown in FIG. 2, such as, but not limited to, additional photonic combiners, additional beam splitters, additional phase shifters, linear photonic amplifiers, photonic attenuators, and/or photonic amplitude thresholders. Furthermore, the constituent circuits of the photonic circuit 205 that may act as photonic NAND gates (e.g., the photonic gates 215 and 225) may be replaced by alternative photonic circuits with substantially same operations, inverse-designed gates, or gates designed using other optimization techniques for photonic design.

The laser 202 may generate and emit the photonic input signal 206 of one or more wavelengths (or modes). Alternatively, the photonic input signal 206 may be generated by another photonic circuit having an output port coupled to the first input port of the photonic circuit 205 that represents a “data” (or “D”) signal port of the photonic circuit 205. In such a case, the photonic input signal 206 may represent a photonic data signal injected into the first input port of the photonic circuit 205. The photonic input signal 206 may be a light signal of corresponding input amplitudes (that each corresponds to logical “1” or logical “0”), corresponding input phases and/or corresponding input modes (i.e., input light spatial distribution and/or input wavelengths) provided at the output port of the laser 202 and injected into the first input port of the photonic circuit 205, i.e., into the first input port of the photonic combiner 216. The laser 202 may include one or more laser emitters, each laser emitter being configured to generate and emit the photonic input signal 206 of a respective wavelength. The one or more laser emitters of the laser 202 may be instructed (i.e., triggered) by at least one processor (e.g., optical processor, electronic processor, electro-optical processor, etc.) coupled to the one or more laser emitters to generate the photonic input signal 206 of one or more specific wavelengths. The output port of the laser 202 may represent, e.g., a set of one or more waveguides, a set of one or more waveguide polarizations, a set of one or more waveguide modes, a set of one or more light wavelengths, a set of one or more signals radiated by the laser 202, etc.

The laser 204 may generate and emit the photonic input signal 208 of one or more wavelengths (or modes). Alternatively, the photonic input signal 208 may be generated by another photonic circuit having an output port coupled to the second input port of the photonic circuit 205 that represents a “clock” (or “C”) signal port of the photonic circuit 205. In such a case, the photonic input signal 208 may represent a photonic clock signal injected into the second input port of the photonic circuit 205. The photonic input signal 208 may be a light signal of corresponding input amplitudes (that each corresponds to logical “1” or logical “0”), corresponding input phases and/or corresponding input modes (i.e., input light spatial distribution and/or input wavelengths) provided at the output port of the laser 204 and injected into the second input port of the photonic circuit 205, i.e., into the input port of the beam splitter 210. The laser 204 may include one or more laser emitters, each laser emitter being configured to generate and emit the photonic input signal 208 of a respective wavelength. The one or more laser emitters of the laser 204 may be instructed (i.e., triggered) by at least one processor (e.g., optical processor, electronic processor, electro-optical processor, etc.) coupled to the one or more laser emitters to generate the photonic input signal 208 of one or more specific wavelengths. The output port of the laser 204 may represent, e.g., a set of one or more waveguides, a set of one or more waveguide polarizations, a set of one or more waveguide modes, a set of one or more light wavelengths, a set of one or more signals radiated by the laser 204, etc.

The beam splitter 210 may receive, at its input port, the photonic input signal 208 generated by the laser 204. The input port of the beam splitter 210 may represent, e.g., a waveguide, a waveguide polarization, a waveguide mode, a light wavelength, etc. The input port of the beam splitter 210 may also represent the second input port of the photonic circuit 205. The beam splitter 210 is a linear photonic component that splits the received photonic input signal 208 into two photonic signals 212, 214. Each photonic signal 212, 214 may be output at a respective output port of the beam splitter 210. A set of output ports of the beam splitter 210 may represent, e.g., a set of waveguides, a set of waveguide polarizations, a set of waveguide modes, a set of light wavelengths, signals radiated by the beam splitter 210, etc. The photonic signals 212 and 214 produced by the beam splitter 210 may be passed to the photonic combiner 216 and the photonic combiner 230, respectively.

The photonic combiner 216 may receive, at its first input port, the photonic input signal 206 generated by the laser 202. The photonic combiner 216 may further receive, at its second input port, the photonic signal 212 generated by the beam splitter 210. The set of input ports of the photonic combiner 216 may represent, e.g., a set of waveguides, a set of waveguide polarizations, a set of waveguide modes, a set of light wavelengths, etc. The first input port of the photonic combiner 216 may also represent the first input port of the photonic circuit 205. The photonic combiner 216 may generate a photonic signal 222 by combining the photonic input signal 206 and the photonic signal 212. The photonic signal 222 may be output at an output port of the photonic combiner 216. The output port of the photonic combiner 216 may represent, e.g., a waveguide, a waveguide polarization, a waveguide mode, a light wavelength, a signal radiated by the photonic combiner 216, etc. The photonic signal 222 generated by the photonic combiner 216 may be passed to the photonic combiner 226.

The phase shifter 218 of the photonic gate 215 may receive a bias signal 220 at an input port of the phase shifter 218. The input port of the phase shifter 218 may represent, e.g., a waveguide, a waveguide polarization, a waveguide mode, a light wavelength, etc. The input port of the phase shifter 218 may also represent a third input port of the photonic circuit 205. The bias signal 220 that is input to the phase shifter 218 is a light signal of a defined amplitude level that is constant over time. The bias signal 220 may be generated by, e.g., a photonic local source coupled to the input port of the phase shifter 218 (not shown in FIG. 2). The phase shifter 218 is a linear photonic component that generates a photonic signal 224 by shifting a phase of the received bias signal 220. For example, the phase shifter 218 may apply a phase shift of x radians to the bias signal 220, i.e., the photonic signal 224 may represent an inverted version of the bias signal 220. The photonic signal 224 may be output at an output port of the phase shifter 218. The output port of the phase shifter 218 may represent, e.g., a waveguide, a waveguide polarization, a waveguide mode, a light wavelength, a signal radiated by the phase shifter 218, etc. The photonic signal 224 generated by the phase shifter 218 may be passed to the photonic combiner 226.

The photonic combiner 226 may receive, at its first input port, the photonic signal 222 generated by the photonic combiner 216. The photonic combiner 226 may further receive, at its second input port, the photonic signal 224 generated by, and output from, the phase shifter 218. The set of input ports of the photonic combiner 226 may represent, e.g., a set of waveguides, a set of waveguide polarizations, a set of waveguide modes, a set of light wavelengths, etc. The photonic combiner 226 may generate the photonic output signal 228 by combining the photonic signal 222 and the photonic signal 224. Note that the phase shifter 218 and the photonic combiner 226 may effectively subtract the bias signal 220 from the photonic signal 222 output from the first photonic combiner 216 in the photonic gate 215 to generate the photonic output signal 228. Note also that the photonic combiner 216, the phase shifter 218 and the photonic combiner 226 form the photonic gate 215 that operates as a linear NAND photonic logic gate. The photonic output signal 228 may be output at an output port of the photonic combiner 226. The output port of the photonic combiner 226 may represent, e.g., a waveguide, a waveguide polarization, a waveguide mode, a light wavelength, a signal radiated by the photonic combiner 226, etc. The output port of the photonic combiner 226 may also represent a first output port of the photonic circuit 205. The photonic output signal 228 generated by the photonic combiner 226 may be passed to the photonic combiner 230.

The photonic combiner 230 may receive, at its first input port, the photonic output signal 228 generated by the photonic combiner 226. The photonic combiner 230 may further receive, at its second input port, the photonic signal 214 generated by the beam splitter 210. The set of input ports of the photonic combiner 230 may represent, e.g., a set of waveguides, a set of waveguide polarizations, a set of waveguide modes, a set of light wavelengths, etc. The photonic combiner 230 may generate a photonic signal 236 by combining the photonic output signal 228 and the photonic signal 214. The photonic signal 236 may be output at an output port of the photonic combiner 230. The output port of the photonic combiner 230 may represent, e.g., a waveguide, a waveguide polarization, a waveguide mode, a light wavelength, a signal radiated by the photonic combiner 230, etc. The photonic signal 236 generated by the photonic combiner 230 may be passed to the photonic combiner 240.

The phase shifter 232 may receive a bias signal 234 at an input port of the phase shifter 232. The input port of the phase shifter 232 may represent, e.g., a waveguide, a waveguide polarization, a waveguide mode, a light wavelength, etc. The input port of the phase shifter 232 may also represent a fourth input port of the photonic circuit 205. The bias signal 234 that is input to the phase shifter 232 is a light signal of a defined amplitude level that is constant over time. The bias signal 234 may be generated by, e.g., a photonic local source coupled to the input port of the phase shifter 232 (not shown in FIG. 2). The phase shifter 232 is a linear photonic component that generates a photonic signal 238 by shifting a phase of the received bias signal 234. For example, the phase shifter 232 may apply a phase shift of x radians to the bias signal 234, i.e., the photonic signal 238 may represent an inverted version of the bias signal 234. The photonic signal 238 may be output at an output port of the phase shifter 232. The output port of the phase shifter 232 may represent, e.g., a waveguide, a waveguide polarization, a waveguide mode, a light wavelength, a signal radiated by the phase shifter 232, etc. The photonic signal 238 generated by the phase shifter 232 may be passed to the photonic combiner 240.

The photonic combiner 240 may receive, at its first input port, the photonic signal 236 generated by the photonic combiner 230. The photonic combiner 240 may further receive, at its second input port, the photonic signal 238 generated by the phase shifter 232. The set of input ports of the photonic combiner 240 may represent, e.g., a set of waveguides, a set of waveguide polarizations, a set of waveguide modes, a set of light wavelengths, etc. The photonic combiner 240 may generate the photonic output signal 242 by combining the photonic signal 236 and the photonic signal 238. Note that the phase shifter 232 and the photonic combiner 240 may effectively subtract the bias signal 234 from the photonic signal 236 to generate the photonic output signal 242. Note also that the photonic combiner 230, the phase shifter 232 and the photonic combiner 240 form the photonic gate 225 that operates as a linear NAND photonic logic gate. The photonic output signal 242 may be output at an output port of the photonic combiner 240. The output port of the photonic combiner 240 may represent, e.g., a waveguide, a waveguide polarization, a waveguide mode, a light wavelength, a signal radiated by the photonic combiner 240, etc. The output port of the photonic combiner 240 may also represent a second output port of the photonic circuit 205.

Note that the photonic circuit 205 effectively operates as a photonic NAND-based pre-flip-flop gate, where the photonic input signal 206 corresponds to the “D” (or “data”) input of the photonic NAND-based pre-flip-flop gate, the photonic input signal 208 corresponds to the “C” (or “clock”) input of the photonic NAND-based pre-flip-flop gate, the photonic output signal 228 corresponds to the “S” (or “set”) output of the photonic NAND-based pre-flip-flop gate, and the photonic output signal 242 corresponds to the “R” (or “reset”) output of the photonic NAND-based pre-flip-flop gate. The photonic circuit 205 thus satisfies the truth table of the NAND-based pre-flip-flop gate: (1) when amplitudes of the photonic input signals 206, 208 corresponds to logical “0s”, amplitudes of the photonic output signals 228, 242 corresponds to logical “1s”; (2) when amplitudes of the photonic input signals 206, 208 corresponds to logical “0” and “1” respectively, amplitudes of the photonic output signals 228, 242 corresponds to logical “1” and logical “0” respectively; (3) when amplitudes of the photonic input signals 206, 208 corresponds to logical “1” and “0” respectively, amplitudes of the photonic output signals 228, 242 corresponds to logical “1s”; and (4) when amplitudes of the photonic input signals 206, 208 corresponds to logical “s”, amplitudes of the photonic output signals 228, 242 corresponds to logical “0” and logical “1” respectively. The photonic circuit 205 may satisfy the truth table of the NAND-based pre-flip-flop gate for a set of one or more wavelengths of the photonic input signals 206, 208 that correspond to the same set of wavelengths of the photonic output signals 228, 242.

### Photonic Register

FIG. 3 illustrates an example photonic system 300 with a photonic circuit 305 that operates as a photonic D-type register, in accordance with some embodiments. In addition to the photonic circuit 305, the photonic system 300 may include a laser 302 coupled to a first input port of the photonic circuit 305 and a laser 304 coupled to a second input port of the photonic circuit 305. Other input ports of the photonic circuit 305 may be bias signal ports, each coupled to a respective signal line for a bias signal source. The laser 302 may generate a photonic input signal 306 injected into the first input port of the photonic circuit 305, and the laser 304 may generate a photonic input signal 308 injected into the second input port of the photonic circuit 305.

The photonic circuit 305 may generate photonic output signals 324 and 330 based on the photonic input signals 306 and 308 while operating as the photonic D-type register. The photonic circuit 305 may include a beam splitter 310, the photonic gate 215, the photonic gate 225, the photonic gate 115 and the photonic gate 125. An input port of the beam splitter 310 may be coupled to an output port of the laser 304, a first output port of the beam splitter 310 may be coupled to a second input port of the photonic gate 215 (i.e., the second input port of the photonic combiner 216), and a second output port of the beam splitter 310 may be coupled to a second input port of the photonic gate 225 (e.g., the second input port of the photonic combiner 230). A first input port of the photonic gate 215 (e.g., the first input port of the photonic combiner 216) may be coupled to an output port of the laser 302. An output port of the photonic gate 215 (e.g., the output port of the photonic combiner 226) may be coupled to a first input port of the photonic gate 225 (i.e., the first input port of the photonic combiner 230) as well as to a first input port of the photonic gate 125 (i.e., the first input port of the photonic combiner 128). An output port of the photonic gate 225 (i.e., the output port of the photonic combiner 240) may be coupled to a first input port of the photonic gate 115 (i.e., the first input port of the photonic combiner 110). A second input port of the photonic gate 115 (i.e., the second input port of the photonic combiner 110) may be coupled to an output port of the photonic gate 125 (i.e., the output port of the photonic combiner 134), and an output port of the photonic gate 115 (i.e., the output port of the photonic combiner 120) may be coupled to a second input port of the photonic gate 125 (i.e., the second input port of the photonic combiner 128). The output port of the photonic gate 115 (i.e., the output port of the photonic combiner 120) may represent a first output port of the photonic circuit 305; and the output port of the photonic gate 125 (i.e., the output port of the photonic combiner 134) may represent a second output port of the photonic circuit 305. It is noted that the input/output ports may be coupled through signal transmission lines (or signal lines). The photonic circuit 305 may include fewer or additional components not shown in FIG. 3, such as, but not limited to, additional photonic combiners, additional beam splitters, phase shifters, linear photonic amplifiers, photonic attenuators, and/or photonic amplitude thresholders. Furthermore, alternative photonic circuits with substantially same operations, inverse-designed gates, or gates designed using other optimization techniques for photonic design may replace the constituent gates of the photonic circuit 305 that may act as photonic NAND gates (e.g., the photonic gates 115, 125, 215, 225).

The laser 302 may generate and emit the photonic input signal 306 of one or more wavelengths (or modes). Alternatively, the photonic input signal 306 may be generated by another photonic circuit having an output port coupled to the first input port of the photonic circuit 305 that represents a “data” (or “D”) signal port of the photonic circuit 305. In such a case, the photonic input signal 306 may represent a photonic data signal injected into the first input port of the photonic circuit 305. The photonic input signal 306 may be a light signal of corresponding input amplitudes (that each corresponds to logical “1” or logical “0”), corresponding input phases and/or corresponding input modes (i.e., input light spatial distribution and/or input wavelengths) provided at the output port of the laser 302 and injected into the first input port of the photonic circuit 305, i.e., into the first input port of the photonic gate 215. The laser 302 may include one or more laser emitters, each laser emitter being configured to generate and emit the photonic input signal 306 of a respective wavelength. The one or more laser emitters of the laser 302 may be instructed (i.e., triggered) by at least one processor (e.g., optical processor, electronic processor, electro-optical processor, etc.) coupled to the one or more laser emitters to generate the photonic input signal 306 of one or more specific wavelengths. The output port of the laser 302 may represent, e.g., a set of one or more waveguides, a set of one or more waveguide polarizations, a set of one or more waveguide modes, a set of one or more light wavelengths, a set of one or more signals radiated by the laser 302, etc.

The laser 304 may generate and emit the photonic input signal 308 of one or more wavelengths (or modes). Alternatively, the photonic input signal 308 may be generated by another photonic circuit having an output port coupled to the second input port of the photonic circuit 305 that represents a “clock” (or “C”) signal port of the photonic circuit 305. In such a case, the photonic input signal 308 may represent a photonic clock signal injected into the second input port of the photonic circuit 305. The photonic input signal 308 may be a light signal of corresponding input amplitudes (that each corresponds to logical “1” or logical “0”), corresponding input phases and/or corresponding input modes (i.e., input light spatial distribution and/or input wavelengths) provided at the output port of the laser 304 and injected into the second input port of the photonic circuit 305, i.e., into the input port of the beam splitter 310. The laser 304 may include one or more laser emitters, each laser emitter being configured to generate and emit the photonic input signal 308 of a respective wavelength. The one or more laser emitters of the laser 304 may be instructed (i.e., triggered) by at least one processor (e.g., optical processor, electronic processor, electro-optical processor, etc.) coupled to the one or more laser emitters to generate the photonic input signal 308 of one or more specific wavelengths. The output port of the laser 304 may represent, e.g., a set of one or more waveguides, a set of one or more waveguide polarizations, a set of one or more waveguide modes, a set of one or more light wavelengths, a set of one or more signals radiated by the laser 304, etc.

The beam splitter 310 may receive, at its input port, the photonic input signal 308 generated by the laser 304. The input port of the beam splitter 310 may represent, e.g., a waveguide, a waveguide polarization, a waveguide mode, a light wavelength, etc. The input port of the beam splitter 310 may also represent the second input port of the photonic circuit 305. The beam splitter 310 is a linear photonic component that splits the received photonic input signal 308 into two photonic signals 312, 314. Each photonic signal 312, 314 may be output at a respective output port of the beam splitter 310. A set of output ports of the beam splitter 310 may represent, e.g., a set of waveguides, a set of waveguide polarizations, a set of waveguide modes, a set of light wavelengths, signals radiated by the beam splitter 310, etc. The photonic signals 312 and 314 produced by the beam splitter 310 may be passed to the photonic gate 215 and the photonic gate 225, respectively.

The photonic gate 215 may generate a photonic signal 318 using the photonic input signal 306, the photonic signal 312 generated by the beam splitter 310 and a bias signal 316. The bias signal 316 is a light signal of a defined amplitude level that is constant over time. The bias signal 316 may be generated by, e.g., a photonic local source. The bias signal 316 may be input to a bias signal port of the photonic gate 215, i.e., to the input port of the phase shifter 218 within the photonic gate 215. As aforementioned in relation to FIG. 2, the photonic gate 215 may operate as a linear NAND photonic gate. Hence, the photonic gate 215 may generate the photonic signal 318 as the NAND logic function of the photonic input signal 306 and the photonic signal 312 while applying the bias signal 316 with the defined amplitude level. The photonic signal 318 generated by the photonic gate 215 may be passed to both the photonic gate 225 and the photonic gate 125.

The photonic gate 225 may generate a photonic signal 322 using the photonic signal 318 generated by the photonic gate 215, the photonic signal 314 generated by the beam splitter 310 and a bias signal 320. The bias signal 320 is a light signal of a defined amplitude level that is constant over time. The bias signal 320 may be generated by, e.g., a photonic local source. The bias signal 320 may be input to a bias signal port of the photonic gate 225, i.e., to the input port of the phase shifter 232 within the photonic gate 225. As aforementioned in relation to FIG. 2, the photonic gate 225 may operate as a linear NAND photonic gate. Hence, the photonic gate 225 may generate the photonic signal 322 as the NAND logic function of the photonic signal 318 and the photonic signal 314 while applying the bias signal 320 with the defined amplitude level. The photonic signal 322 generated by the photonic gate 225 may be passed to the photonic gate 115.

The photonic gate 115 may generate the photonic output signal 330 using the photonic signal 322 generated by the photonic gate 225, the photonic output signal 324 fed back from the output port of the photonic gate 125 and a bias signal 326. The bias signal 326 is a light signal of a defined amplitude level that is constant over time. The bias signal 326 may be generated by, e.g., a photonic local source. The bias signal 326 may be input to a bias signal port of the photonic gate 115, i.e., to the input port of the phase shifter 114 within the photonic gate 115. As aforementioned in relation to FIG. 1, the photonic gate 115 may operate as a linear NAND photonic gate. Hence, the photonic gate 115 may generate the photonic output signal 330 as the NAND logic function of the photonic signal 322 and the photonic output signal 324 while applying the bias signal 326 with the defined amplitude level. The photonic output signal 330 generated by the photonic gate 115 may be passed to the photonic gate 125. Furthermore, the photonic output signal 330 may be output at the first output port of the photonic circuit 305.

The photonic gate 125 may generate the photonic output signal 324 using the photonic output signal 330 generated by the photonic gate 115, the photonic signal 318 generated by the photonic gate 215 and a bias signal 328. The bias signal 328 is a light signal of a defined amplitude level that is constant over time. The bias signal 328 may be generated by, e.g., a photonic local source. The bias signal 328 may be input to a bias signal port of the photonic gate 125, i.e., to the input port of the phase shifter 126 within the photonic gate 125. As aforementioned in relation to FIG. 1, the photonic gate 125 may operate as a linear NAND photonic gate. Hence, the photonic gate 125 may generate the photonic output signal 324 as the

NAND logic function of the photonic signal 318 and the photonic output signal 330 while applying the bias signal 328 with the defined amplitude level. The photonic output signal 324 generated by the photonic gate 125 may be fed back to the photonic gate 115. Furthermore, the photonic output signal 324 may be output at the second output port of the photonic circuit 305.

Note that the photonic circuit 305 effectively operates as a photonic D-type register (or photonic D-type flip-flop), where the photonic input signal 306 correspond to the “D” (or “data”) input of the photonic D-type register, the photonic input signal 308 corresponds to the “C” (or “clock”) input of the photonic D-type register, the photonic output signal 330 corresponds to the “Q1” output of the photonic D-type register, and the photonic output signal 324 corresponds to the “Q2” output of the photonic D-type register. The photonic circuit 305 may thus satisfy the truth table of the photonic D-type register for a set of one or more wavelengths of the photonic input signals 306, 308 that correspond to the same set of wavelengths of the photonic output signals 324, 330. The photonic circuit 305 may be part of a photonic register of a photonic processor.

### Photonic Counter

FIG. 4 illustrates an example two-bit photonic counter circuit 400, in accordance with some embodiments. The photonic counter circuit 400 may include a photonic D-type flip-flop 405A and a photonic D-type flip-flop 405B. The photonic D-type flip-flops 405A, 405B may have an identical structure, such as the structure of the photonic D-type register shown in FIG. 3. A first input port (e.g., “Data” or “D” input port) of the photonic D-type flip-flop 405A may be coupled to a second output port (e.g., “Q2” output port) of the photonic D-type flip-flop 405A. A second input port (e.g., “Clock” or “C” input port) of the photonic D-type flip-flop 405A may be coupled to a clock source 402. The second input port of the photonic D-type flip-flop 405A may represent an input port of the photonic counter circuit 400. The second output port of the photonic D-type flip-flop 405A may be coupled to a second input port (e.g., “Clock” or “C” input port) of the photonic D-type flip-flop 405B. A first input port (e.g., “Data” or “D” input port) of the photonic D-type flip-flop 405B may be coupled to a second output port (e.g., “Q2” output port) of the photonic D-type flip-flop 405B. The second output port of the photonic D-type flip-flop 405B may represent an output port of the photonic counter circuit 400. The photonic counter circuit 400 may include fewer or additional components not shown in FIG. 4, such as, but not limited to, photonic combiners, beam splitters, phase shifters, linear photonic amplifiers, photonic attenuators, and/or photonic amplitude thresholders.

The photonic D-type flip-flop 405A may receive, at its first input port, a photonic signal 406 generated at the second output port of the D-type flip-flop 405A. The photonic D-type flip-flop 405A may further receive, at its second input port, the photonic clock signal 404 generated by the clock source 402. The clock source 402 may be a photonic circuit or photonic oscillator that generates the photonic clock signal 404 of a defined rate that includes one or more wavelengths (or modes). The set of input ports of the photonic D-type flip-flop 405A may represent, e.g., a set of waveguides, a set of waveguide polarizations, a set of waveguide modes, a set of light wavelengths, etc. The first output port (i.e., “Q1” output port) of the photonic D-type flip-flop 405A may be open, i.e., not being coupled to the photonic D-type flip-flop 405B or any other component of the photonic counter circuit 400. Alternatively, the first output port of the photonic D-type flip-flop 405A may be coupled to another photonic circuit (not shown in FIG. 4). The photonic D-type flip-flop 405A may generate, at its second output port, the photonic signal 406 based on the photonic clock signal 404 and a previous version of the photonic signal 406 fed back from the second output port of the photonic D-type flip-flop 405A to the first input port of the photonic D-type flip-flop 405A. As shown in FIG. 4, the rate of the photonic signal 406 may be lower (e.g., approximately two times lower) than the rate of the photonic clock signal 404. The set of output ports of the photonic D-type flip-flop 405A may represent, e.g., a set of waveguides, a set of waveguide polarizations, a set of waveguide modes, a set of light wavelengths, signals radiated by the photonic D-type flip-flop 405A, etc. The photonic signal 406 generated by the photonic D-type flip-flop 405A may be passed to the photonic D-type flip-flop 405B.

The photonic D-type flip-flop 405B may receive, at its first input port, a photonic signal 408 generated at the second output port of the D-type flip-flop 405B. The photonic D-type flip-flop 405B may further receive, at its second input port, the photonic signal 406 generated by the photonic D-type flip-flop 405A. The set of input ports of the photonic D-type flip-flop 405B may represent, e.g., a set of waveguides, a set of waveguide polarizations, a set of waveguide modes, a set of light wavelengths, etc. The first output port (i.e., “Q1” output port) of the photonic D-type flip-flop 405B may be open, i.e., not being coupled to any component of the photonic counter circuit 400. Alternatively, the first output port of the photonic D-type flip-flop 405B may be coupled to another photonic circuit (not shown in FIG. 4). The photonic D-type flip-flop 405B may generate, at its second output port, the photonic signal 408 based on the photonic signal 406 and a previous version of the photonic signal 408 fed back from the second output port of the photonic D-type flip-flop 405B to the first input port of the photonic D-type flip-flop 405B. As shown in FIG. 4, the rate of the photonic signal 408 may be lower (e.g., approximately four times lower) than the rate of the photonic clock signal 404. The set of output ports of the photonic D-type flip-flop 405B may represent, e.g., a set of waveguides, a set of waveguide polarizations, a set of waveguide modes, a set of light wavelengths, signals radiated by the photonic D-type flip-flop 405B, etc.

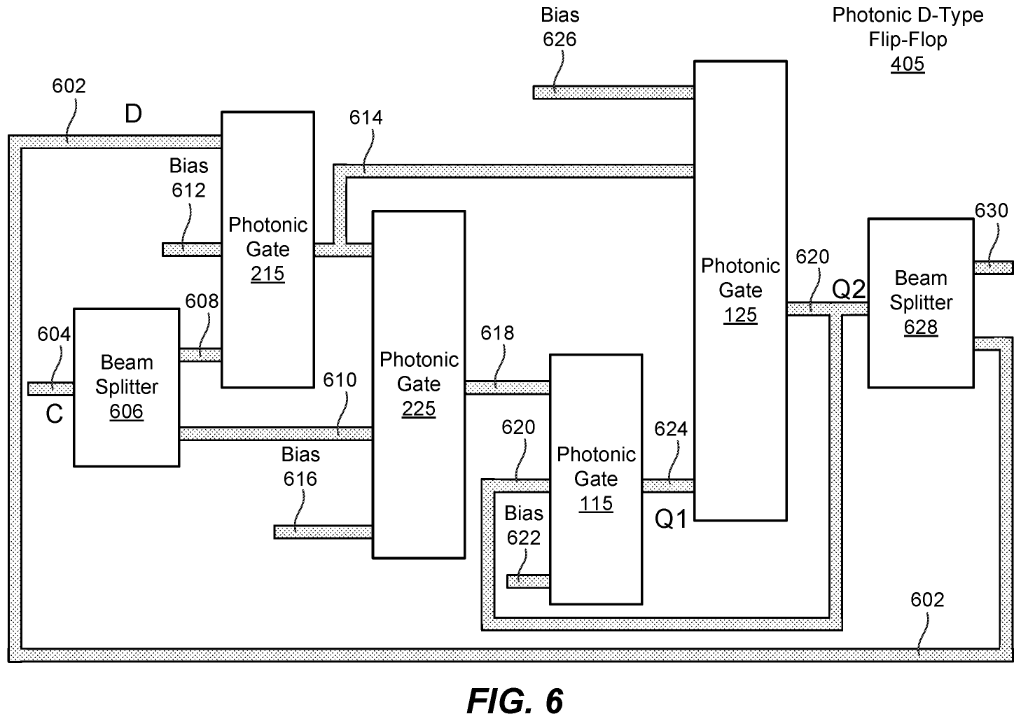

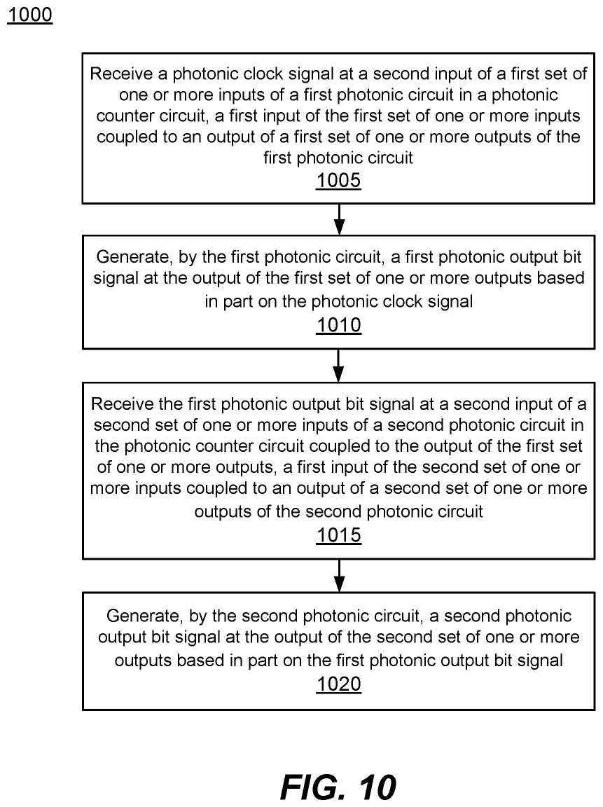

Changes of amplitudes (i.e., pulses) of the photonic signals 406 and 408 may represent a bit count (i.e., total of two bits) for a number of pulses (i.e., changes of amplitudes) in the photonic clock signal 404. For example, as shown in a graph 410 in FIG. 4, for a total of three completed pulses of the photonic clock signal 404, the two-bit logic value of the photonic signals 406 and 408 is “11” that represents three completed pulses of the photonic clock signal 404. To represent a higher bit count (i.e., larger number of completed pulses of the photonic clock signal 404), the photonic counter circuit 400 may include one or more additional photonic D-type flip-flops, where a second input port (i.e., “Clock” or “C” input port) of each additional D-type flip-flop may be coupled to a second output port (i.e., “Q2” output port) of a previous D-type flip-flop in a sequence of D-type flip-flops in the photonic counter circuit 400. Additional details about the structure and operation of the D-type flip-flops 405A, 405B are described in relation to FIG. 6 and FIG. 10.

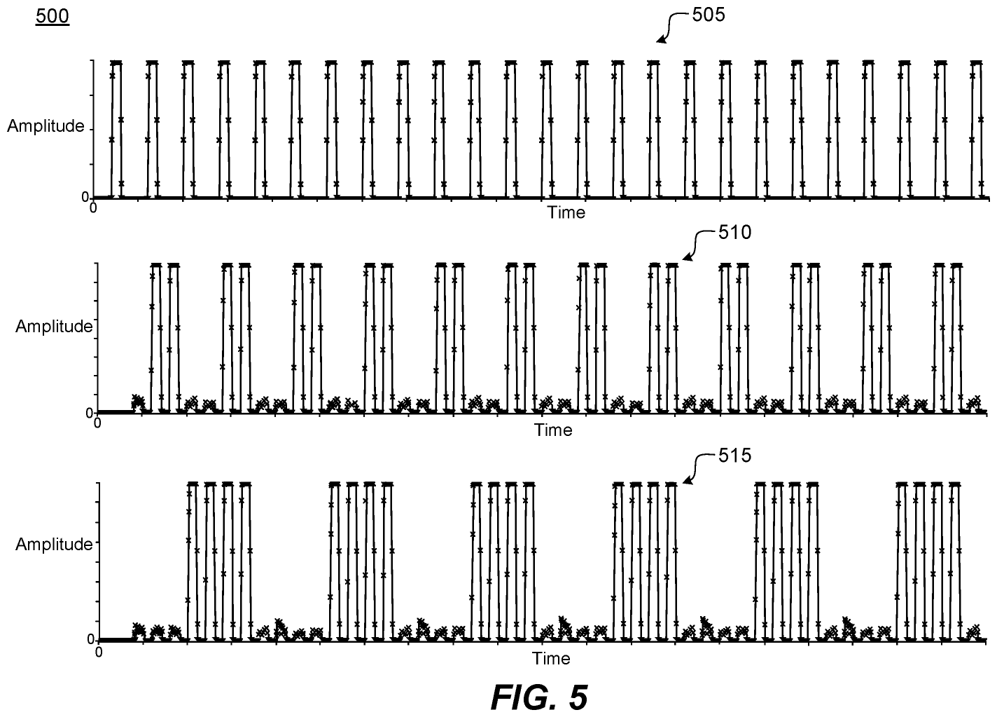

FIG. 5 illustrates an example graph 500 of photonic signals associated with the two-bit photonic counter circuit 400, in accordance with some embodiments. A photonic signal 505 may be an embodiment of the photonic clock signal 404 injected into the input port of the photonic counter circuit 400 (i.e., the second input port of the photonic D-type flip-flop 405A). A photonic signal 510 may be an embodiment of the photonic signal 406 generated by the photonic D-type flip-flop 405A and output at the second output port of the photonic D-type flip-flop 405A. In general, the photonic signal 510 may represent an output signal from a 1-bit D-type register. A photonic signal 515 may be an embodiment of the photonic signal 408 generated by the photonic D-type flip-flop 405B and output at the second output port of the photonic D-type flip-flop 405B. In general, the photonic signal 515 may represent an output signal from a 1-bit D-type register. Thus, the photonic signals 505 and 510 may represent the outputs of a 2-bit photonic counter circuit (e.g., the two-bit photonic counter circuit 400). Note that the photonic D-type flip-flops 405A, 405B may include one or more photonic amplitude thresholders (e.g., nonlinear active amplitude thresholders) so that amplitudes of the generated photonic signals 510 and 515 may not be attenuated below a threshold amount relative to amplitudes of the photonic input signal 505.

FIG. 6 illustrates an example photonic D-type flip-flop 405 (i.e., the photonic D-type flip-flop 405A or the photonic D-type flip-flop 405B) of the photonic counter circuit 400, in accordance with some embodiments. The photonic D-type flip-flop 405 may generate photonic output signals 624 and 620 based on photonic input signals 602 and 604. The photonic D-type flip-flop 405 may include a beam splitter 606, the photonic gate 215, the photonic gate 225, the photonic gate 115, the photonic gate 125, and a beam splitter 628. An input port of the beam splitter 606 may be coupled to a clock signal line (i.e., “Clock” or “C” signal line) for receiving the photonic input signal 604 as a photonic clock signal, a first output port of the beam splitter 606 may be coupled to a second input port of the photonic gate 215 (i.e., the second input port of the photonic combiner 216), and a second output port of the beam splitter 606 may be coupled to a second input port of the photonic gate 225 (e.g., the second input port of the photonic combiner 230).

A first input port of the photonic gate 215 (e.g., the first input port of the photonic combiner 216) may be coupled to a data signal line (i.e., “Data” or “D” signal line) for receiving a data signal, and the first input port of the photonic gate 215 may be further coupled to a second output port of the beam splitter 628. An output port of the photonic gate 215 (e.g., the output port of the photonic combiner 226) may be coupled to a first input port of the photonic gate 225 (i.e., the first input port of the photonic combiner 230) as well as to a first input port of the photonic gate 125 (i.e., the first input port of the photonic combiner 128). An output port of the photonic gate 225 (i.e., the output port of the photonic combiner 240) may be coupled to a first input port of the photonic gate 115 (i.e., the first input port of the photonic combiner 110).

A second input port of the photonic gate 115 (i.e., the second input port of the photonic combiner 110) may be coupled to an output port of the photonic gate 125 (i.e., the output port of the photonic combiner 134), and an output port of the photonic gate 115 (i.e., the output port of the photonic combiner 120) may be coupled to a second input port of the photonic gate 125 (i.e., the second input port of the photonic combiner 128). The output port of the photonic gate 125 may be further coupled to an input port of the beam splitter 628. The output port of the photonic gate 115 (i.e., the output port of the photonic combiner 120) may represent a first output port (i.e., “Q1” output port) of the photonic D-type flip flop 405; the output port of the photonic gate 125 (i.e., the output port of the photonic combiner 134) may represent a second output port (i.e., “Q2” output port) of the photonic D-type flip flop 405; and a first output port of the beam splitter 628 may represent an output signal port of the photonic D-type flip flop 405. It is noted that the input/output ports may be coupled through signal transmission lines (or signal lines). The photonic D-type flip flop 405 may include fewer or additional components not shown in FIG. 6, such as, but not limited to, photonic combiners, additional beam splitters, phase shifters, inverse designed gates, linear photonic amplifiers, photonic attenuators, and/or photonic amplitude thresholders.

The photonic input signal 602 may be a light signal of corresponding input amplitudes (that each corresponds to logical “1” or logical “0”), corresponding input phases injected into the “Data” signal port of the photonic D-type flip flop 405, i.e., into the first input port of the photonic gate 215. The photonic input signal 602 may include one or more wavelengths (or input modes). The photonic input signal 602 may be a data signal that is fed back from a second output port of the beam splitter 628.

The photonic input signal 604 may be a light signal of corresponding input amplitudes (that each corresponds to logical “1” or logical “0”), corresponding input phases and/or corresponding input modes (i.e., input light spatial distribution and/or input wavelengths) injected into the “Clock” signal port of the photonic D-type flip flop 405, i.e., into the input port of the beam splitter 606. The photonic input signal 604 may include one or more wavelengths (or input modes). The photonic input signal 604 may represent a photonic clock signal and may be generated by another photonic circuit (e.g., another photonic D-type flip flop 405) having an output port coupled to the input port of the beam splitter 606.

The beam splitter 606 may receive, at its input port, the photonic input signal 604. The input port of the beam splitter 606 may represent, e.g., a waveguide, a waveguide polarization, a waveguide mode, a light wavelength, etc. The input port of the beam splitter 606 may also represent a second input port (“Clock” or “C” input port) of the photonic D-type flip-flop 405. The beam splitter 606 is a linear photonic component that splits the received photonic input signal 604 into two photonic signals 608, 610. Each photonic signal 608, 610 may be output at a respective output port of the beam splitter 606. A set of output ports of the beam splitter 606 may represent, e.g., a set of waveguides, a set of waveguide polarizations, a set of waveguide modes, a set of light wavelengths, signals radiated by the beam splitter 606, etc. The photonic signals 608 and 610 produced by the beam splitter 606 may be passed to the photonic gate 215 and the photonic gate 225, respectively.

The photonic gate 215 may generate a photonic signal 614 using the photonic input signal 602, the photonic signal 608 generated by the beam splitter 606 and a bias signal 612. The bias signal 612 is a light signal of a defined amplitude level that is constant over time. The bias signal 612 may be generated by, e.g., a photonic local source. The bias signal 612 may be input to a bias signal port of the photonic gate 215, i.e., to the input port of the phase shifter 218 within the photonic gate 215. As aforementioned in relation to FIG. 2, the photonic gate 215 may operate as a linear NAND photonic gate. Hence, the photonic gate 215 may generate the photonic signal 614 as the NAND logic function of the photonic input signal 602 and the photonic signal 608 while applying the bias signal 612 with the defined amplitude level. The photonic signal 614 generated by the photonic gate 215 may be passed to both the photonic gate 225 and the photonic gate 125.

The photonic gate 225 may generate a photonic signal 618 using the photonic signal 614 generated by the photonic gate 215, the photonic signal 610 generated by the beam splitter 606 and a bias signal 616. The bias signal 616 is a light signal of a defined amplitude level that is constant over time. The bias signal 616 may be generated by, e.g., a photonic local source. The bias signal 616 may be input to a bias signal port of the photonic gate 225, i.e., to the input port of the phase shifter 232 within the photonic gate 225. As aforementioned in relation to FIG. 2, the photonic gate 225 may operate as a linear NAND photonic gate. Hence, the photonic gate 225 may generate the photonic signal 618 as the NAND logic function of the photonic signal 614 and the photonic signal 610 while applying the bias signal 616 with the defined amplitude level. The photonic signal 618 generated by the photonic gate 225 may be passed to the photonic gate 115.

The photonic gate 115 may generate the photonic output signal 624 using the photonic signal 618 generated by the photonic gate 225, the photonic output signal 620 fed back from the output port of the photonic gate 125 and a bias signal 622. The bias signal 622 is a light signal of a defined amplitude level that is constant over time. The bias signal 622 may be generated by, e.g., a photonic local source. The bias signal 622 may be input to a bias signal port of the photonic gate 115, i.e., to the input port of the phase shifter 114 within the photonic gate 115. As aforementioned in relation to FIG. 1, the photonic gate 115 may operate as a linear NAND photonic gate. Hence, the photonic gate 115 may generate the photonic output signal 624 as the NAND logic function of the photonic signal 618 and the photonic output signal 620 while applying the bias signal 326 with the defined amplitude level. The photonic output signal 624 generated by the photonic gate 115 may be passed to the photonic gate 125.

The photonic gate 125 may generate the photonic output signal 620 using the photonic output signal 624 generated by the photonic gate 115, the photonic signal 614 generated by the photonic gate 215 and a bias signal 626. The bias signal 626 is a light signal of a defined amplitude level that is constant over time. The bias signal 626 may be generated by, e.g., a photonic local source. The bias signal 626 may be input to a bias signal port of the photonic gate 125, i.e., to the input port of the phase shifter 126 within the photonic gate 125. As aforementioned in relation to FIG. 1, the photonic gate 125 may operate as a linear NAND photonic gate. Hence, the photonic gate 125 may generate the photonic output signal 620 as the NAND logic function of the photonic signal 614 and the photonic output signal 624 while applying the bias signal 626 with the defined amplitude level. The photonic output signal 620 generated by the photonic gate 125 may be fed back to the photonic gate 115. Furthermore, the photonic output signal 620 may be passed to the beam splitter 628.

The beam splitter 628 may receive, at its input port, the photonic output signal 620. The input port of the beam splitter 628 may represent, e.g., a waveguide, a waveguide polarization, a waveguide mode, a light wavelength, etc. The input port of the beam splitter 628 may be coupled to the second output port (“Q2” output port) of the photonic D-type flip-flop 405. The beam splitter 628 is a linear photonic component that splits the received photonic output signal 620 into two photonic signals 630, 602. Each photonic signal 630, 602 may be output at a respective output port of the beam splitter 628. A set of output ports of the beam splitter 628 may represent, e.g., a set of waveguides, a set of waveguide polarizations, a set of waveguide modes, a set of light wavelengths, signals radiated by the beam splitter 628, etc. The photonic signal 602 produced by the beam splitter 628 may be fed back to the first input port of the photonic gate 215 that represents the first input port (i.e., “Data” or “D” input port) of the photonic D-type flip-flop 405. The other photonic signal 630 produced by the beam splitter 628 may be output from the photonic D-type flip-flop 405 for injection into some other photonic circuit (e.g., some other photonic D-type flip-flop 405).

### Example Process Flows

FIG. 7 is a flowchart illustrating an example method 700 for operating a photonic circuit as a photonic SR flip-flop, in accordance with some embodiments. The operations of method 700 may be performed at, e.g., the photonic circuit 105. The photonic circuit may be part of a photonic processor. Alternatively, the photonic circuit may be a photonic device separate from the photonic processor. The photonic circuit may be deployed in a computing system that further includes a non-transitory computer-readable storage medium (e.g., optical, electrical, or electro-optical memory) for storing computer-executable instructions and data. The computing system may be an optical computing system (i.e., silicon photonics platform), an electronic computing system, some other type of computing system, or some combination thereof.

The photonic circuit receives 705 a first photonic input signal (e.g., the photonic input signal 106) at a first input of a first set of one or more inputs of a first photonic gate (e.g., the photonic gate 115) of the photonic circuit. The first input of the first set of one or more inputs of the first photonic gate may be configured to receive the first photonic input signal that includes a first set of one or more multiplexed light signals of a set of one or more wavelengths. The photonic circuit receives 710, at a second input of the first set of one or more inputs of the first photonic gate, a second photonic output signal (e.g., the photonic output signal 136) that was generated by a second photonic gate (e.g., the photonic gate 125) of the photonic circuit. A first bias signal (e.g., the bias signal 116) may be input to a third input of the first set of one or more inputs of the first photonic gate, the first bias signal having a first amplitude value that is constant over time.

The photonic circuit generates 715, by the first photonic gate at an output of a first set of one or more outputs of the first photonic gate, a first photonic output signal (e.g., the photonic output signal 122) based at least in part on the first photonic input signal and the second photonic output signal. The output of the first set of one or more outputs of the first photonic gate may be configured to output the first photonic output signal that includes a third set of one or more multiplexed light signals of the set of one or more wavelengths. The first photonic gate may include a first photonic combiner (e.g., the photonic combiner 110), a phase shifter (e.g., the phase shifter 114) and a second photonic combiner (e.g., the photonic combiner 120) that is coupled to an output of the first photonic combiner and an output of the phase shifter, an output of the second photonic combiner representing the output of the first set of one or more outputs of the first photonic gate. A first input of the first photonic combiner may be configured to receive the first photonic input signal, and a second input of the first photonic combiner may be coupled to the output of the second set of one or more outputs of the second photonic gate and configured to receive the second photonic output signal.

The photonic circuit receives 720 a second photonic input signal (e.g., the photonic input signal 108) at a first input of a second set of one or more inputs of the second photonic gate. The first input of the second set of one or more inputs of the second photonic gate may be configured to receive the second photonic input signal that includes a second set of one or more multiplexed light signals of the set of one or more wavelengths. The photonic circuit receives 725 the first photonic output signal at a second input of the second set of one or more inputs of the second photonic gate. A second bias signal (e.g., the bias signal 124) may be input to a third input of the second set of one or more inputs of the second photonic gate, the second bias signal having a second amplitude value that is constant over time.

The photonic circuit generates 730, by the second photonic gate at an output of a second set of one or more outputs of the second photonic gate, the second photonic output signal based at least in part on the second photonic input signal and the first photonic output signal. The output of the second set of one or more outputs of the second photonic gate may be configured to output the second photonic output signal that includes a fourth set of one or more multiplexed light signals of the set of one or more wavelengths. The second photonic gate may include a first photonic combiner (e.g., the photonic combiner 128), a phase shifter (e.g., the phase shifter 126) and a second photonic combiner (e.g., the photonic combiner 134) that is coupled to an output of the first photonic combiner and an output of the phase shifter, an output of the second photonic combiner representing the output of the second set of one or more outputs of the second photonic gate. A first input of the first photonic combiner may be configured to receive the second photonic input signal, and a second input of the first photonic combiner may be coupled to the output of the first photonic gate and configured to receive the first photonic output signal.

FIG. 8 is a flowchart illustrating an example method 800 for operating a photonic circuit as a photonic NAND-based pre-flip-flop gate, in accordance with some embodiments. The operations of method 800 may be performed at, e.g., the photonic circuit 205. The photonic circuit may be part of a photonic processor. Alternatively, the photonic circuit may be a photonic device separate from the photonic processor. The photonic circuit may be part of a photonic register of the photonic processor, and the photonic circuit may be configured to operate as a photonic NAND-based pre-flip-flop gate. The photonic circuit may be deployed in a computing system that further includes a non-transitory computer-readable storage medium (e.g., optical, electrical, or electro-optical memory) for storing computer-executable instructions and data. The computing system may be an optical computing system (i.e., silicon photonics platform), an electronic computing system, some other type of computing system, or some combination thereof.

The photonic circuit receives 805 a first photonic input signal (e.g., the photonic input signal 206) at a first input of a first set of one or more inputs of a first photonic gate (e.g., the photonic gate 215) of the photonic circuit. The first input of the first set of one or more inputs of the first photonic gate may be configured to receive the first photonic input signal that includes a first set of one or more multiplexed light signals of a set of one or more wavelengths. The photonic circuit receives 810, at a second input of the first set of one or more inputs of the first photonic gate, a second photonic input signal (e.g., the photonic signal 212 obtained from the photonic input signal 208 via the beam splitter 210). The second input of the first set of one or more inputs of the first photonic gate may be configured to receive the second photonic input signal that includes a second set of one or more multiplexed light signals of the set of one or more wavelengths. A first bias signal (e.g., the bias signal 220) may be input to a third input of the first set of one or more inputs of the first photonic gate, the first bias signal having a first amplitude value that is constant over time.

The photonic circuit generates 815, by the first photonic gate at an output of a first set of one or more outputs, a first photonic output signal (e.g., the photonic output signal 228) based at least in part on the first photonic input signal and the second photonic input signal. The output of the first set of one or more outputs of the first photonic gate may be configured to output the first photonic output signal that includes a third set of one or more multiplexed light signals of the set of one or more wavelengths. The first photonic gate may include a first photonic combiner (e.g., the photonic combiner 216), a phase shifter (e.g., the phase shifter 218) and a second photonic combiner (e.g., the photonic combiner 226) that is coupled to an output of the first photonic combiner and an output of the phase shifter, an output of the second photonic combiner representing the output of the first set of one or more outputs of the first photonic gate. A first input of the first photonic combiner may be configured to receive the first photonic input signal, and a second input of the first photonic combiner may be configured to receive the second photonic input signal.

The photonic circuit receives 820 the first photonic output signal at a first input of a second set of one or more inputs of a second photonic gate (e.g., the photonic gate 225) of the photonic circuit, the first input of the second set of one or more inputs coupled to an output of the first photonic gate (e.g., the output port of the photonic combiner 226). The photonic circuit receives 825 the second photonic input signal (the photonic signal 214 obtained from the photonic input signal 208 via the beam splitter 210) at a second input of the second set of one or more inputs of the second photonic gate (e.g., the input port of the photonic combiner), the second input of the second set of one or more inputs coupled to the second input of the first set of one or more inputs of the first photonic gate (e.g., via the beam splitter 210). The second input of the second set of one or more inputs of the second photonic gate may be configured to receive the second photonic input signal that includes the second set of one or more multiplexed light signals of the set of one or more wavelengths. A second bias signal (e.g., the bias signal 234) may be input to a third input of the second set of one or more inputs of the second photonic gate, the second bias signal having a second amplitude value that is constant over time.

The photonic circuit generates 830, by the second photonic gate at an output of a second set of one or more outputs, a second photonic output signal (e.g., the photonic output signal 242) based at least in part on the first photonic output signal and the second photonic input signal. The output of the second set of one or more outputs of the second photonic gate may be configured to output the second photonic output signal that includes a fourth set of one or more multiplexed light signals of the set of one or more wavelengths. The second photonic gate may include a first photonic combiner (e.g., the photonic combiner 230), a phase shifter (e.g., the phase shifter 232) and a second photonic combiner (e.g., the photonic combiner 240) that is coupled to an output of the first photonic combiner and an output of the phase shifter, an output of the second photonic combiner representing the output of the second set of one or more outputs of the second photonic gate. A first input of the first photonic combiner of the second photonic gate may be coupled to the output of the first set of one or more outputs of the first photonic gate and configured to receive the first photonic output signal, and a second input of the first photonic combiner of the second photonic gate may be configured to receive the second photonic input signal.

FIG. 9 is a flowchart illustrating an example method 900 for operating a photonic circuit as a photonic D-type register, in accordance with some embodiments. The operations of method 900 may be performed at, e.g., the photonic circuit 305. The photonic circuit may be part of a photonic processor. Alternatively, the photonic circuit may be a photonic device separate from the photonic processor. The photonic circuit may be deployed in a computing system that further includes a non-transitory computer-readable storage medium (e.g., optical, electrical, or electro-optical memory) for storing computer-executable instructions and data. The computing system may be an optical computing system (i.e., silicon photonics platform), an electronic computing system, some other type of computing system, or some combination thereof.

The photonic circuit receives 905 a first photonic input signal (e.g., the photonic input signal 306) at a first input of a first set of one or more inputs (e.g., the first input port of the photonic gate 215) of a first set of one or more cascading photonic gates (e.g., the photonic gates 215, 225) and a second photonic input signal (e.g., the photonic input signal 308, or any of the photonic signals 312, 314 generated from the photonic input signal 308) at a second input of the first set of one or more inputs (e.g., the input port of the beam splitter 310, the second input port of the photonic gate 215, or the second input port of the photonic gate 225). The first input of the first set of one or more inputs may be configured to receive the first photonic input signal that includes a first set of one or more multiplexed light signals of a set of one or more wavelengths, and the second input of the first set of one or more inputs may be configured to receive the second photonic input signal that includes a second set of one or more multiplexed light signals of the set of one or more wavelengths.

The photonic circuit generates 910, by the first set of one or more cascading photonic gates, a first intermediate output signal (e.g., the photonic signal 318) at a first output of a first set of one or more outputs (e.g., the output port of the photonic gate 318) of the first set of one or more cascading photonic gates based at least in part on the first photonic input signal and the second photonic input signal. The photonic circuit generates 915, by the first set of one or more cascading photonic gates, a second intermediate output signal (e.g., the photonic signal 322) at a second output of the first set of one or more outputs (e.g., the output port of the photonic gate 225) based at least in part on the first intermediate output signal and the second photonic input signal.

The first set of one or more cascading photonic gates may include a first photonic gate (e.g., the photonic gate 215) having one or more first inputs and one or more first outputs, a first input of the one or more first inputs (e.g., the first input port of the photonic gate 215) configured to receive the first photonic input signal, and a second input of the one or more first inputs (e.g., the second input port of the photonic gate 215) configured to receive the second photonic input signal (e.g., the photonic signal 312). The first photonic gate may generate the first intermediate output signal at an output of the one or more first outputs (e.g., the output port of the photonic gate 215) based at least in part on the first photonic input signal and the second photonic input signal. A first bias signal (e.g., the bias signal 316) may be input to a third input of the one or more first inputs (e.g., the bias signal port of the photonic gate 215), and an amplitude value of the first bias signal may be set to be constant over time. The first photonic gate may include a first photonic combiner (e.g., the photonic combiner 216), a phase shifter (e.g., the phase shifter 218) and a second photonic combiner (e.g., the photonic combiner 226) that is coupled to an output of the first photonic combiner and an output of the phase shifter, an output of the second photonic combiner coupled to the output of the one or more first outputs. A first input of the first photonic combiner may be configured to receive the first photonic input signal, and a second input of the first photonic combiner may be configured to receive the second photonic input signal

The first set of one or more cascading photonic gates may further include a second photonic gate (e.g., the photonic gate 225) having one or more second inputs and one or more second outputs, a first input of the one or more second inputs (e.g., the first input port of the photonic gate 225) coupled to the output of the one or more first outputs (e.g., the output port of the photonic gate 215) and configured to receive the first intermediate output signal, and a second input of the one or more second inputs (e.g., the second input port of the photonic gate 225) coupled to the second input of the one or more first inputs and configured to receive the second photonic input signal (e.g., the photonic signal 314). The second photonic gate may generate the second intermediate output signal at an output of the one or more second outputs (e.g., the output port of the photonic gate 225) based at least in part on the first intermediate output signal and the second photonic input signal. A second bias signal (e.g., the bias signal 320) may be input to a third input of the one or more second inputs (e.g., the bias signal port of the photonic gate 225), and an amplitude value of the second bias signal may be set to be constant over time. The second photonic gate may include a first photonic combiner (e.g., the photonic combiner 230), a phase shifter (e.g., the phase shifter 232) and a second photonic combiner (e.g., the photonic combiner 240) that is coupled to an output of the first photonic combiner and an output of the phase shifter, an output of the second photonic combiner coupled to the output of the one or more second outputs. A first input of the first photonic combiner may be coupled to the first output of the first photonic gate and configured to receive the first intermediate output signal, and a second input of the first photonic combiner may be coupled to the second input of the first photonic gate and configured to receive the second photonic input signal.

The photonic circuit receives 920 the first intermediate output signal at a second input of a second set of one or more inputs (e.g., the first input port of the photonic gate 125) of a second set of one or more cascading photonic gates (e.g., the photonic gates 115, 125) and the second intermediate output signal at a first input of the second set of one or more inputs (e.g., the first input port of the photonic gate 115) of the second set of one or more cascading photonic gates coupled to the second output of the first set of one or more outputs of the first set of one or more cascading photonic gates.

The photonic circuit generates 925, by the second set of one or more cascading photonic gates, a first photonic output signal (e.g., the photonic output signal 330) at a first output of a second set of one or more outputs (e.g., the output port of the photonic gate 115) of the second set of one or more cascading photonic gates based at least in part on the second intermediate output signal and a second photonic output signal (e.g., the photonic output signal 324) that was output by the second set of one or more cascading photonic gates at a second output of the second set of one or more outputs (e.g., the output port of the photonic gate 125). The first output of the second set of one or more outputs may be configured to output the first photonic output signal that includes a third set of one or more multiplexed light signals of the set of one or more wavelengths.

The photonic circuit generates 930, by the second set of one or more cascading photonic gates, the second photonic output signal at the second output of the second set of one or more outputs based at least in part on the first intermediate output signal and the first photonic output signal. The second output of the second set of one or more outputs may be configured to output the second photonic output signal that includes a fourth set of one or more multiplexed light signals of the set of one or more wavelengths.

The second set of one or more cascading photonic gates may include a first photonic gate (e.g., the photonic gate 115) having one or more first inputs and one or more first outputs, an output of the one or more first outputs (e.g., the output port of the photonic gate 115) coupled to the first output of the second set of one or more cascading photonic gates, a first input of the one or more first inputs (e.g., the first input port of the photonic gate 115) coupled to the second output of the first set of one or more cascading photonic gates (e.g., the output port of the photonic gate 225) and configured to receive the second intermediate output signal, a second input of the one or more first inputs (e.g., the second input port of the photonic gate 115) coupled to the second output of the second set of one or more cascading photonic gates (e.g., the output port of the photonic gate 125) and configured to receive the second photonic output signal. The first photonic gate of the second set of one or more photonic gates may generate the first photonic output signal at the output of the one or more first outputs based at least in part on the second intermediate output signal and the second photonic output signal. A third bias signal (e.g., the bias signal 326) may be input to a third input of the one or more first inputs (e.g., the bias signal port of the photonic gate 115) of the second set of one or more photonic gates, and an amplitude value of the third bias signal may be set to be constant over time. The first photonic gate of the second set of one or more photonic gates may include a first photonic combiner (e.g., the photonic combiner 110), a phase shifter (e.g., the phase shifter 114) and a second photonic combiner (e.g., the photonic combiner 120) that is coupled to an output of the first photonic combiner and an output of the phase shifter, an output of the second photonic combiner coupled to the first output of the second set of one or more cascading photonic gates. A first input of the first photonic combiner may be coupled to the second output of the first set of one or more cascading photonic gates and configured to receive the second intermediate output signal, and a second input of the first photonic combiner may be coupled to the second output of the second set of one or more cascading photonic gates and configured to receive the second photonic output signal.

The second set of one or more cascading photonic gates may further include a second photonic gate (e.g., the photonic gate 125) having one or more second inputs and one or more second outputs, an output of the one or more second outputs (e.g., the output port of the photonic gate 125) coupled to the second output of the second set of one or more cascading photonic gates, a first input of the one or more second inputs (e.g., the first input port of the photonic gate 125) coupled to the first output of the first set of one or more cascading photonic gates and configured to receive the first intermediate output signal, a second input of the one or more second inputs (e.g., the second input port of the photonic gate 125) coupled to the output of the one or more first outputs of the second set of one or more photonic gates and configured to receive the first photonic output signal. The second photonic gate may generate the second photonic output signal at the output of the one or more second outputs based at least in part on the first intermediate output signal and the first photonic output signal. A fourth bias signal (e.g., the bias signal 328) may be input to a third input of the one or more second inputs (e.g., the bias signal port of the photonic gate 125), and an amplitude value of the fourth bias signal may be set to be constant over time. The second photonic gate may include a first photonic combiner (e.g., the photonic combiner 128), a phase shifter (e.g., the phase shifter 126) and a second photonic combiner (e.g., the photonic combiner 134) that is coupled to an output of the first photonic combiner and an output of the phase shifter, an output of the second photonic combiner coupled to the second output of the second set of one or more cascading photonic gates. A first input of the first photonic combiner may be coupled to the first output of the first set of one or more cascading photonic gates and configured to receive the first intermediate output signal, and a second input of the first photonic combiner may be coupled to the first output of the second set of one or more cascading photonic gates and configured to receive the first photonic output signal.

FIG. 10 is a flowchart illustrating an example method 1000 for operating a photonic counter circuit, in accordance with some embodiments. The operations of method 1000 may be performed at, e.g., the photonic counter circuit 400. The photonic counter circuit may be part of a photonic processor. Alternatively, the photonic counter circuit may be a photonic device separate from the photonic processor. The photonic counter circuit may be deployed in a computing system that further includes a non-transitory computer-readable storage medium (e.g., optical, electrical, or electro-optical memory) for storing computer-executable instructions and data. The computing system may be an optical computing system (i.e., silicon photonics platform), an electronic computing system, some other type of computing system, or some combination thereof.

The photonic counter circuit receives 1005 a photonic clock signal (e.g., the photonic clock signal 404 or the photonic signal 604) at a second input of a first set of one or more inputs of a first photonic circuit (e.g., the photonic D-type flip-flop 405A), a first input of the first set of one or more inputs coupled to an output of a first set of one or more outputs of the first photonic circuit. The second input of the first set of one or more inputs may be configured to receive the photonic clock signal that includes a first set of one or more multiplexed light signals of a set of one or more wavelengths. The photonic counter circuit generates 1010, by the first photonic circuit, a first photonic output bit signal (e.g., the photonic signal 406, the photonic output signal 620, or the photonic signal 602) at the output of the first set of one or more outputs based in part on the photonic clock signal. The output of the first set of one or more outputs may be configured to output the first photonic output bit signal that includes a second set of one or more multiplexed light signals of the set of one or more wavelengths. A rate of the photonic clock signal may be two times higher than a rate of the first photonic output bit signal.

The first photonic circuit (e.g., the photonic D-type flip-flop 405A) may include a first set of one or more cascading photonic gates (e.g., the beam splitter 606, the photonic gate 215 and/or the photonic gate 225 in FIG. 6) having at least one first input and at least one first output. A first input of the at least one first input may be coupled to a second output of the at least one second output of the second set of one or more photonic gates and configured to receive the second photonic output bit signal, and a second input of the at least one first input may be configured to receive the photonic clock signal. The first set of one or more cascading photonic gates may generate, at a first output of the at least one first output (e.g., the output port of the photonic gate 215 in FIG. 6), a first intermediate output signal (e.g., the photonic signal 614) based at least in part on the second photonic output bit signal and the photonic clock signal. The first set of one or more cascading photonic gates may further generate, at a second output of the at least one first output (e.g., the output port of the photonic gate 225 in FIG. 6), a second intermediate output signal (e.g., the photonic signal 618) based at least in part on the first intermediate output signal and the photonic clock signal.

The first set of one or more cascading photonic gates (e.g., the beam splitter 606, the photonic gate 215 and/or the photonic gate 225 in FIG. 6) may include a first photonic gate (e.g., the photonic gate 215 with or without the beam splitter 606) having one or more first inputs and one or more first outputs. The first set of one or more cascading photonic gates may further include a second photonic gate (e.g., the photonic gate 225 in FIG. 6) having one or more second inputs and one or more second outputs. A first input of the one or more first inputs (e.g., the first input port of the photonic gate 215 in FIG. 6) may be coupled to the second output of the second set of one or more cascading photonic gates (e.g., the second output port of the beam splitter 628) and configured to receive the second photonic output bit signal (e.g., the photonic signal 406 or the photonic input signal 602), and a second input of the one or more first inputs (the input port of the beam splitter 606) may be configured to receive the photonic clock signal (e.g., the photonic clock signal 404 or the photonic input signal 604). The first photonic gate (e.g., the photonic gate 215 in FIG. 6) may generate the first intermediate output signal (e.g., the photonic signal 614) at an output of the one or more first outputs (e.g., the output port of the photonic gate 215 in FIG. 6) based at least in part on the second photonic output bit signal of second set of one or more cascading photonic gates and the photonic clock signal. A first input of the one or more second inputs (e.g., the first input port of the photonic gate 225 in FIG. 6) may be coupled to the output of the one or more first outputs (e.g., the output port of the photonic gate 215 in FIG. 6) and configured to receive the first intermediate output signal (e.g., the photonic signal 614). A second input of the one or more second inputs (e.g., the second input port of the photonic gate 225 in FIG. 6) may be coupled to the second input of the one or more first inputs and configured to receive the photonic clock signal (e.g., the photonic signal 610 obtained by splitting the photonic input signal 604). The second photonic gate (e.g., the photonic gate 225 in FIG. 6) may generate the second intermediate output signal (e.g., the photonic signal 618) at an output of the one or more second outputs (e.g., the output port of the photonic gate 225 in FIG. 6) based at least in part on the first intermediate output signal (e.g., the photonic signal 614) and the photonic clock signal (e.g., the photonic signal 610 obtained by splitting the photonic input signal 604). A first bias signal (e.g., the bias signal 612) may be input to a third input of the one or more first inputs (e.g., the bias signal port of the photonic gate 215 in FIG. 6), the first bias signal having a first amplitude value that is constant over time. A second bias signal (e.g., the bias signal 616) may be input to a third input of the one or more second inputs (e.g., the bias signal port of the photonic gate 225 in FIG. 6), the second bias signal having a second amplitude value that is constant over time.

The first photonic gate (e.g., the photonic gate 215 in FIG. 6) may include a first photonic combiner (e.g., the photonic combiner 216 in FIG. 2), a phase shifter (e.g., the phase shifter 218) and a second photonic combiner (e.g., the photonic combiner 226) that is coupled to an output of the first photonic combiner and an output of the phase shifter, an output of the second photonic combiner may be coupled to the output of the one or more first outputs (e.g., the output port of the photonic gate 215 in FIG. 6). A first input of the first photonic combiner may be configured to receive the second photonic output bit signal (e.g., the photonic signal 602 obtained from the photonic output signal 620), and a second input of the first photonic combiner may be configured to receive the photonic clock signal (e.g., the photonic signal 608 obtained from the photonic input signal 604). The second photonic gate (e.g., the photonic gate 225 in FIG. 6) may include a first photonic combiner (e.g., the photonic combiner 230 in FIG. 2), a phase shifter (e.g., the phase shifter 232) and a second photonic combiner (e.g., the photonic combiner 240) that is coupled to an output of the first photonic combiner and an output of the phase shifter, an output of the second photonic combiner coupled to the second output of the one or more second outputs (e.g., the output port of the photonic gate 225 in FIG. 6) of the first set of one or more cascaded photonic gates. A first input of the first photonic combiner may be coupled to the first output of the at least one first output of the first set of one or more cascaded photonic gates and configured to receive the first intermediate output signal (e.g., the photonic signal 614), and a second input of the first photonic combiner may be configured to receive the photonic clock signal (e.g., the photonic signal 610 obtained from the photonic input signal 604).

The first photonic circuit (e.g., the photonic D-type flip-flop 405A) may further include a second set of one or more cascading photonic gates (e.g., the photonic gate 115, the photonic gate 125 and/or the beam splitter 628 in FIG. 6) having at least one second input and at least one second output. A first input of the at least one second input (e.g., the first input port of the photonic gate 115 in FIG. 6) may be coupled to the second output of the first set of one or more cascaded photonic gates and configured to receive the second intermediate output signal (e.g., the photonic signal 618), and a second input of the at least one second input (e.g., the first input port of the photonic gate 125 in FIG. 6) may be coupled to the first output of the first set of one or more cascaded photonic gates and configured to receive the first intermediate output signal (e.g., the photonic signal 614). The second set of one or more cascading photonic gates may generate, at a first output of the at least one second output (e.g., the output port of the photonic gate 115 in FIG. 6), a first photonic output signal (e.g., the photonic output signal 624) based at least in part on the second intermediate output signal (e.g., the photonic signal 618) and the second photonic output bit signal (e.g., the photonic output signal 620) that was output at a second output of the second set of one or more cascading photonic gates (e.g., the output port of the photonic gate 125 in FIG. 6). The second set of one or more cascading photonic gates may further generate, at a second output of the at least one second output (e.g., the output port of the photonic gate 125 in FIG. 6), the second photonic output bit signal (e.g., the photonic signal 406 or the photonic output signal 620) based at least in part on the first intermediate output signal (e.g., the photonic signal 614) and the first photonic output signal (e.g., the photonic output signal 624).

The second set of one or more cascading photonic gates (e.g., the photonic gate 115, the photonic gate 125 and/or the beam splitter 628 in FIG. 6) may include a first photonic gate (e.g., the photonic gate 115 in FIG. 6) having one or more first inputs and one or more first outputs, an output of the one or more first outputs (e.g., the output port of the photonic gate 115 in FIG. 6) coupled to the first output of the second set of one or more cascading photonic gates (e.g., the first output port “Q1” of the photonic D-type flip-flop 405 in FIG. 6). The second set of one or more cascading photonic gates may further include a second photonic gate (e.g., the photonic gate 125 in FIG. 6) having one or more second inputs and one or more second outputs, an output of the one or more second outputs (e.g., the output port of the photonic gate 125 in FIG. 6) may be coupled to the second output of the second set of one or more cascading photonic gates (e.g., the second output port “Q2” of the photonic D-type flip-flop 405 in FIG. 6). A first input of the one or more first inputs (e.g., the first input port of the photonic gate 115 in FIG. 6) may be coupled to the second output of the first set of one or more cascading photonic gates (e.g., the output port of the photonic gate 225 in FIG. 6) and configured to receive the second intermediate output signal (e.g., the photonic signal 618). A second input of the one or more first inputs (e.g., the second input port of the photonic gate 115 in FIG. 6) may be coupled to the second output of the at least one second output (e.g., the output port of the photonic gate 125 in FIG. 6) and configured to receive the second photonic output bit signal (e.g., the photonic output signal 620). The first photonic gate (e.g., the photonic gate 115 in FIG. 6) may generate the first photonic output signal (e.g., the photonic output signal 624) at the output of the one or more first outputs of the second set of one or more cascading photonic gates (e.g., at the output port of the photonic gate 115 in FIG. 6) based at least in part on the second intermediate output signal (e.g., the photonic signal 618) and the second photonic output bit signal (e.g., the photonic output signal 620). A first input of the one or more second inputs (e.g., the first input port of the photonic gate 125 in FIG. 6) may be coupled to the first output of the first set of one or more cascading photonic gates (e.g., the output port of the photonic gate 215 in FIG. 6) and configured to receive the first intermediate output signal (e.g., the photonic signal 614). A second input of the one or more second inputs (e.g., the second input port of the photonic gate 125 in FIG. 6) may be coupled to the output of the one or more first outputs of the second set of one or more cascading photonic gates (e.g., the output port of the photonic gate 115 in FIG. 6) and configured to receive the first photonic output bit signal (e.g., the photonic output signal 624). The second photonic gate may generate the second photonic output bit signal (e.g., the photonic output signal 620 or the photonic signal 602 obtained by splitting the photonic output signal 620) at the output of the one or more second outputs (e.g., the output port of the photonic gate 125 in FIG. 6 or the output port of the beam splitter 628) based at least in part on the first intermediate output signal (e.g., the photonic signal 614) and the first photonic output signal of the second set of one or more cascading photonic gates (e.g., the photonic output signal 624). A first bias signal of the second set of one or more cascading photonic gates (e.g., the bias signal 622) may be input to a third input of the one or more first inputs (e.g., the bias signal port of the photonic gate 115), the first bias signal having a first amplitude value that is constant over time. A second bias signal of the second set of one or more cascading photonic gates (e.g., the bias signal 626) may be input to a third input of the one or more second inputs (e.g., the bias signal port of the photonic gate 125), the second bias signal having a second amplitude value that is constant over time.

The first photonic gate of the second set of one or more cascading photonic gates (e.g., the photonic gate 115 in FIG. 6) may include a first photonic combiner (e.g., the photonic combiner 110 in FIG. 1), a phase shifter (e.g., the phase shifter 114) and a second photonic combiner (e.g., the photonic combiner 120) that is coupled to an output of the first photonic combiner and an output of the phase shifter, an output of the second photonic combiner coupled to the first output of the at least one second output of the second set of one or more cascading photonic gates (e.g., the first output port “Q1” of the photonic D-type flip-flop 405 in FIG. 6). A first input of the first photonic combiner may be configured to receive the second intermediate output signal (e.g., the photonic signal 618), and a second input of the first photonic combiner may be coupled to the second output of the second set of one or more cascading photonic gates (e.g., the second output port “Q2” of the photonic D-type flip-flop 405 in FIG. 6) and configured to receive the second photonic output bit signal (e.g., the photonic output signal 620). The second photonic gate of the second set of one or more cascading photonic gates (e.g., the photonic gate 125 in FIG. 6) may include a first photonic combiner (e.g., the photonic combiner 128 in FIG. 1), a phase shifter (e.g., the phase shifter 126) and a second photonic combiner (e.g., the photonic combiner 134) that is coupled to an output of the first photonic combiner and an output of the phase shifter, an output of the second photonic combiner coupled to the second output of the second set of one or more cascading photonic gates (e.g., the second output port “Q2” of the photonic D-type flip-flop 405 in FIG. 6). A first input of the first photonic combiner may be coupled to the first output of the first set of one or more cascading photonic gates (e.g., the output port of the photonic gate 215 in FIG. 6) and configured to receive the first intermediate output signal (e.g., the photonic signal 614). A second input of the first photonic combiner may be coupled to the first output of the second set of one or more cascading photonic gates (e.g., the first output port “Q1” of the photonic D-type flip-flop 405 in FIG. 6) and configured to receive the first photonic output signal (e.g., the photonic output signal 624).

The photonic counter circuit receives 1015 the first photonic output bit signal (e.g. the second output bit signal of the D-type flip-flop 405A) at a second input of a second set of one or more inputs of a second photonic circuit (e.g., the photonic D-type flip-flop 405B) coupled to the output of the first set of one or more outputs of the first photonic circuit, a first input of the second set of one or more inputs coupled to an output of a second set of one or more outputs of the second photonic circuit. The photonic counter circuit generates 1020, by the second photonic circuit, a second photonic output bit signal (e.g., the photonic signal 408) at the output of the second set of one or more outputs based in part on the first photonic output bit signal. The output of the second set of one or more outputs may be configured to output the second photonic output bit signal that includes a third set of one or more multiplexed light signals of the set of one or more wavelengths. The rate of the first photonic output bit signal may be two times higher than a rate of the second photonic output bit signal. The first photonic output bit signal and the second photonic output bit signal may together represent a bit count of a number of pulses of the photonic clock signal.

The second photonic circuit (e.g., the photonic D-type flip-flop 405B) may include a first set of one or more cascading photonic gates (e.g., the beam splitter 606, the photonic gate 215 and/or the photonic gate 225 in FIG. 6) having at least one first input and at least one first output, and a second set of one or more cascading photonic gates (e.g., the photonic gate 115, the photonic gate 125 and/or the beam splitter 628 in FIG. 6) having at least one second input and at least one second output. A first input of the at least one first input (e.g., the first input port of the photonic gate 215 in FIG. 6) may be coupled to a second output of the at least one second output (e.g., the second output port of the beam splitter 628) and configured to receive the second photonic output bit signal (e.g., the photonic signal 408 or the photonic signal 602 generated by the photonic D-type flip-flop 405 in FIG. 6). A second input of the at least one first input (e.g., the input port of the beam splitter 606) may be coupled to the output of the at least first output of the first photonic circuit (e.g., the second output port of the D-type flip-flop 405 in FIG. 6) and configured to receive the first photonic output bit signal (e.g., the photonic signal 408 or the photonic input signal 604) of the photonic counter circuit. The first set of one or more cascading photonic gates (e.g., the beam splitter 606, the photonic gate 215 and/or the photonic gate 225 in FIG. 6) may generate, at a first output of the at least one first output (e.g., the output port of the photonic gate 215 in FIG. 6), a first intermediate output signal (e.g., the photonic signal 614) based at least in part on the first photonic output bit signal (e.g., the photonic input signal 604 generated by the photonic D-type flip-flop 405A) and the second photonic output bit signal (e.g., the photonic signal 602 fed back from the second output port of the beam splitter 628). The first set of one or more cascading photonic gates may further generate, at a second output of the at least one first output (e.g., the output port of the photonic gate 225 in FIG. 6), a second intermediate output signal (e.g., the photonic signal 618) based at least in part on the first intermediate output signal (e.g., the photonic signal 614) and the first photonic output bit signal (e.g., the photonic signal 610 obtained by splitting the photonic input signal 604 that was generated by the photonic D-type flip-flop 405A) of the photonic counter circuit.

A second input of the at least one second input (e.g., the first input port of the photonic gate 125 in FIG. 6) may be coupled to the first output of the at least one first output of the first set of one or more cascading photonic gates (the output port of the photonic gate 215 in FIG. 6) and configured to receive the first intermediate output signal (e.g., the photonic signal 614). A first input of the at least one second input (e.g., the second input port of the photonic gate 115 in FIG. 6) may be coupled to the second output of the at least one first output of the first set of one or more cascading photonic gates (e.g., the output port of the photonic gate 225 in FIG. 6) and configured to receive the second intermediate output signal (e.g., the photonic signal 618). The second set of one or more cascading photonic gates (e.g., the photonic gate 115, the photonic gate 125 and/or the beam splitter 628 in FIG. 6) may generate, at a first output of the at least one second output (e.g., the first output port “Q1” of the photonic D-type flip-flop 405 in FIG. 6), a first photonic output signal (e.g., the photonic output signal 624) based at least in part on the second intermediate output signal (e.g., the photonic signal 618) and the second photonic output bit signal (e.g., the photonic output signal 620) that was output by the second set of one or more cascading photonic gates at the second output of the at least one second output (e.g., the output port of the photonic gate 125 in FIG. 6). The second set of one or more cascading photonic gates may further generate, at the second output of the at least one second output (e.g., the output port of the photonic gate 125 in FIG. 6 or the second output port of the beam splitter 628), the second photonic output bit signal (e.g., the photonic signal 408, the photonic output signal 620 or the photonic signal 602 obtained by splitting the photonic output signal 620) based at least in part on the first intermediate output signal (e.g., the photonic signal 614) and the first photonic output signal (e.g., the photonic output signal 624).

The first set of one or more cascading photonic gates (e.g., the beam splitter 606, the photonic gate 215 and/or the photonic gate 225 in FIG. 6) may include a first photonic gate (the photonic gate 215 with or without the beam splitter 606) having one or more first inputs and one or more first outputs, and a second photonic gate (e.g., the photonic gate 225 in FIG. 6) having one or more second inputs and one or more second outputs. A first input of the one or more first inputs (e.g., the first input port of the photonic gate 215 in FIG. 6) may be coupled to the second output of the at least one second output of the second set of one or more cascading photonic gates (e.g., the second output port of the beam splitter 628) and configured to receive the second photonic output bit signal (e.g., the photonic signal 408 or the photonic signal 602). A second input of the one or more first inputs (e.g., the input port of the beam splitter 606 or the second input port of the photonic gate 215 in FIG. 6) may be configured to receive the first photonic output bit signal of the photonic counter circuit (e.g., the photonic signal 406, the photonic input signal 604 generated by the photonic D-type flip-flop 405A, or the photonic signal 608 generated by splitting the photonic input signal 604). The first photonic gate (e.g., the photonic gate 215 in FIG. 6) may generate the first intermediate output signal (e.g., the photonic signal 614) at the output of the one or more first outputs based at least in part on the second photonic output bit signal (from the second set of one or more cascading photonic gates) and the first photonic output bit signal (from the photonic counter circuit). A first input of the one or more second inputs (e.g., the first input port of the photonic gate 225 in FIG. 6) may be coupled to the output of the one or more first outputs (e.g., the output port of the photonic gate 215 in FIG. 6) and configured to receive the first intermediate output signal (e.g., the photonic signal 614). A second input of the one or more second inputs (e.g., the second input port of photonic gate 225 in FIG. 6) may be coupled to the second input of the one or more first inputs and configured to receive the first photonic output bit signal (e.g., the photonic signal 610 obtained by splitting the photonic input signal 604 generated by the photonic D-type flip-flop 405A) of the photonic counter circuit. The second photonic gate (e.g., the photonic gate 225 in FIG. 6) may generate the second intermediate output signal (e.g., the photonic signal 618) at an output of the one or more second outputs of the first set of one or more cascading photonic gates (e.g., the output port of the photonic gate 225 in FIG. 6) based at least in part on the first intermediate output signal (e.g., the photonic signal 614) and the first photonic output bit signal (e.g., the photonic signal 610) of the photonic counter circuit.

The second set of one or more cascading photonic gates (e.g., the photonic gate 115, the photonic gate 125 and/or the beam splitter 628 in FIG. 6) may include a first photonic gate (e.g., the photonic gate 115 in FIG. 6) having one or more first inputs and one or more first outputs, an output of the one or more first outputs (e.g., the output port of the photonic gate 115 in FIG. 6) coupled to the first output of the at last one second output of the second set of one or more cascading photonic gates (e.g., the first output port “Q1” of the photonic D-type flip flop 405 in FIG. 6). The second set of one or more cascading photonic gates may further include a second photonic gate (e.g., the photonic gate 125 in FIG. 6) having one or more second inputs and one or more second outputs, an output of the one or more second outputs (e.g., the output port of the photonic gate 125 in FIG. 6) coupled to the second output of the at least one second output of the second set of one or more cascading photonic gates (e.g., the second output port “Q2” of the photonic D-type flip flop 405 in FIG. 6). A first input of the one or more first inputs (e.g., the first input port of the photonic gate 115 in FIG. 6) may be coupled to the second output at least one first output of the first set of one or more cascading photonic gates (e.g., the output port of the photonic gate 225 in FIG. 6) and configured to receive the second intermediate output signal (e.g., the photonic signal 618). A second input of the one or more first inputs (e.g., the second input port of the photonic gate 115 in FIG. 6) may be coupled to the second output of the at least one second output of the second set of one or more cascading photonic gates (e.g., the second output port “Q2” in FIG. 6) and configured to receive the second photonic output bit signal (e.g., the photonic output signal 620). The first photonic gate (e.g., the photonic gate 115 in FIG. 6) may generate the first photonic output signal (e.g., the photonic output signal 624) at the output of the one or more first outputs of the second set of one or more cascading photonic gates (e.g., the output port of the photonic gate 115 in FIG. 6) based at least in part on the second intermediate output signal (e.g., the photonic signal 618) and the second photonic output bit signal (e.g., the photonic output signal 620). A first input of the one or more second inputs (e.g., the first input port of the photonic gate 125 in FIG. 6) may be coupled to the first output of the at least one first output of the first set of one or more cascading photonic gates (e.g., the output port of the photonic gate 215 in FIG. 6) and configured to receive the first intermediate output signal (e.g., the photonic signal 614). A second input of the one or more second inputs (e.g., the second input port of the photonic gate 125 in FIG. 6) may be coupled to the output of the one or more first outputs of the second set of one or more cascading photonic gates (e.g., the output port of the photonic gate 115 in FIG. 6) and configured to receive the first photonic output signal (e.g., the photonic output signal 624). The second photonic gate (e.g., the photonic gate 125 in FIG. 6) may generate the second photonic output bit signal (e.g., the photonic output signal 620) at the output of the one or more second outputs (e.g., the output port of the photonic gate 125 in FIG. 6) based at least in part on the first intermediate output signal (e.g., the photonic signal 614) and the first photonic output signal (e.g., the photonic output signal 624) of the second set of one or more cascading photonic gates.

This disclosure presents the implementation of photonic flip-flops, photonic pre-flip-flop gates, photonic registers and photonic counters that can be integrated into photonic processors for supporting high processing speeds of photonic computing. Each of the photonic flip-flops, photonic registers and photonic counters presented herein may be implemented using only a minimal number of thresholders (e.g., electro-optical thresholders, optical thresholders, saturable optical absorbers, semiconductor optical amplifiers, etc.). Furthermore, the photonic pre-flip-flop gates may not require any thresholders. Thus, area sizes of the photonic components presented herein are reduced, while facilitating their power efficiency.

### Additional Considerations

The disclosed configurations beneficially provide for efficient design of photonic logic gates while substantially reducing a number of required numerical design simulations. Moreover, the circuits noted may be designed and simulated with electronic-photonic and/or photonic design automation software program tools and represented as circuit layouts stored in an electronic library. The circuit designs may be retrieved and incorporated into designs of chips including the retrieved design.

The foregoing description of the embodiments of the disclosure has been presented for the purpose of illustration; it is not intended to be exhaustive or to limit the disclosure to the precise forms disclosed. Persons skilled in the relevant art can appreciate that many modifications and variations are possible in light of the above disclosure.

Some portions of this description describe the embodiments of the disclosure in terms of algorithms and symbolic representations of operations on information. These algorithmic descriptions and representations are commonly used by those skilled in the data processing arts to effectively convey the substance of their work to others skilled in the art. While described functionally, computationally, or logically, these operations are understood to be implemented by computer programs or equivalent electrical circuits, microcode, or the like. Furthermore, at times, it has also proven convenient to refer to these arrangements of operations as modules without loss of generality. The described operations and associated modules can be embodied in software, firmware, hardware, or some combination thereof.

Any steps, operations, or processes described herein can be performed or implemented with one or more hardware or software modules, alone or in combination with other devices. In one embodiment, a software module is implemented with a computer program product comprising a computer-readable medium containing computer program code, which a computer processor can execute for performing any or all of the steps, operations, or processes described herein.

Embodiments of the disclosure can also relate to an apparatus for performing the operations herein. This apparatus can be specially constructed for the required purposes, and/or it can include a general-purpose computing device selectively activated or reconfigured by a computer program stored in the computer. Such a computer program can be stored in a non-transitory, tangible computer-readable storage medium or any media suitable for storing electrical instructions coupled to a computer system bus. Furthermore, any computing systems referred to in the specification can include a single processor or architectures employing multiple processor designs for increased computing capability.

Some embodiments of the present disclosure can further relate to a system comprising a processor, at least one computer processor, and a non-transitory computer-readable storage medium. The storage medium can store computer-executable instructions, which, when executed by the compiler operating on at least one computer processor, cause at least one computer processor to be operable for performing the operations and techniques described herein.

Finally, the language used in the specification has been principally selected for readability and instructional purposes, and it has not been selected to delineate or circumscribe the inventive subject matter. It is therefore intended that the scope of the disclosure be limited not by this detailed description but rather by any claims that issue on an application based hereon. Accordingly, the disclosure of the embodiments is intended to be illustrative, but not to limit the scope of the disclosure, which is set forth in the following claims.

What is claimed is:

1. A photonic circuit, comprising:
a first set of one or more cascading photonic gates having a first set of one or more inputs and a first set of one or more outputs, a first input of the first set of one or more inputs configured to receive a first photonic input signal, a second input of the first set of one or more inputs configured to receive a second photonic input signal, the first set of one or more cascading photonic gates configured to:
generate, at a first output of the first set of one or more outputs, a first intermediate output signal based at least in part on the first photonic input signal and the second photonic input signal, and
generate, at a second output of the first set of one or more outputs, a second intermediate output signal based at least in part on the first intermediate output signal and the second photonic input signal; and
a second set of one or more cascading photonic gates having a second set of one or more inputs and a second set of one or more outputs, a first input of the second set of one or more inputs coupled to the second output of the first set of one or more outputs and configured to receive the second intermediate output signal, a second input of the second set of one or more inputs coupled to the first output of the first set of one or more outputs and configured to receive the first intermediate output signal, the second set of one or more cascading photonic gates configured to:
generate, at a first output of the second set of one or more outputs, a first photonic output signal based at least in part on the second intermediate output signal and a second photonic output signal that was output by the second set of one or more cascading photonic gates at a second output of the second set of one or more outputs, and
generate, at the second output of the second set of one or more outputs, the second photonic output signal based at least in part on the first intermediate output signal and the first photonic output signal.

2. The photonic circuit of claim 1, wherein:
the first input of the first set of one or more inputs is configured to receive the first photonic input signal that comprises a first set of one or more multiplexed light signals of a set of one or more wavelengths;
the second input of the first set of one or more inputs is configured to receive the second photonic input signal that comprises a second set of one or more multiplexed light signals of the set of one or more wavelengths;
the first output of the second set of one or more outputs is configured to output the first photonic output signal that comprises a third set of one or more multiplexed light signals of the set of one or more wavelengths; and
the second output of the second set of one or more outputs is configured to output the second photonic output signal that comprises a fourth set of one or more multiplexed light signals of the set of one or more wavelengths.

3. The photonic circuit of claim 1, wherein the first set of one or more cascading photonic gates comprises:
a first photonic gate having one or more first inputs and one or more first outputs, a first input of the one or more first inputs configured to receive the first photonic input signal, a second input of the one or more first inputs configured to receive the second photonic input signal, the first photonic gate configured to generate the first intermediate output signal at an output of the one or more first outputs based at least in part on the first photonic input signal and the second photonic input signal; and
a second photonic gate having one or more second inputs and one or more second outputs, a first input of the one or more second inputs coupled to the output of the one or more first outputs and configured to receive the first intermediate output signal, a second input of the one or more second inputs coupled to the second input of the one or more first inputs and configured to receive the second photonic input signal, the second photonic gate configured to generate the second intermediate output signal at an output of the one or more second outputs based at least in part on the first intermediate output signal and the second photonic input signal.

4. The photonic circuit of claim 3, further comprising:
a first bias signal input to a third input of the one or more first inputs, the first bias signal having a first amplitude value that is constant over time; and
a second bias signal input to a third input of the one or more second inputs, the second bias signal having a second amplitude value that is constant over time.

5. The photonic circuit of claim 3, wherein the first photonic gate comprises a first photonic combiner, a phase shifter and a second photonic combiner that is coupled to an output of the first photonic combiner and an output of the phase shifter, an output of the second photonic combiner coupled to the output of the one or more first outputs.

6. The photonic circuit of claim 5, wherein a first input of the first photonic combiner is configured to receive the first photonic input signal, and a second input of the first photonic combiner is configured to receive the second photonic input signal.

7. The photonic circuit of claim 3, wherein the second photonic gate comprises a first photonic combiner, a phase shifter and a second photonic combiner that is coupled to an output of the first photonic combiner and an output of the phase shifter, an output of the second photonic combiner coupled to the output of the one or more second outputs.

8. The photonic circuit of claim 7, wherein a first input of the first photonic combiner is coupled to the first output of the first photonic gate and configured to receive the first intermediate output signal, and a second input of the first photonic combiner is coupled to the second input of the first photonic gate and configured to receive the second photonic input signal.

9. The photonic circuit of claim 1, wherein the second set of one or more cascading photonic gates comprises:
a first photonic gate having one or more first inputs and one or more first outputs, an output of the one or more first outputs coupled to the first output of the second set of one or more cascading photonic gates, a first input of the one or more first inputs coupled to the second output of the first set of one or more cascading photonic gates and configured to receive the second intermediate output signal, a second input of the one or more first inputs coupled to the second output of the second set of one or more cascading photonic gates and configured to receive the second photonic output signal, the first photonic gate configured to generate the first photonic output signal at the output of the one or more first outputs based at least in part on the second intermediate output signal and the second photonic output signal; and
a second photonic gate having one or more second inputs and one or more second outputs, an output of the one or more second outputs coupled to the second output of the second set of one or more cascading photonic gates, a first input of the one or more second inputs coupled to the first output of the first set of one or more cascading photonic gates and configured to receive the first intermediate output signal, a second input of the one or more second inputs coupled to the output of the one or more first outputs and configured to receive the first photonic output signal, the second photonic gate configured to generate the second photonic output signal at the output of the one or more second outputs based at least in part on the first intermediate output signal and the first photonic output signal.

10. The photonic circuit of claim 9, further comprising:
a first bias signal input to a third input of the one or more first inputs, the first bias signal having a first amplitude value that is constant over time; and
a second bias signal input to a third input of the one or more second inputs, the second bias signal having a second amplitude value that is constant over time.

11. The photonic circuit of claim 9, wherein the first photonic gate comprises a first photonic combiner, a phase shifter and a second photonic combiner that is coupled to an output of the first photonic combiner and an output of the phase shifter, an output of the second photonic combiner coupled to the first output of the second set of one or more cascading photonic gates.

12. The photonic circuit of claim 11, wherein a first input of the first photonic combiner is coupled to the second output of the first set of one or more cascading photonic gates and configured to receive the second intermediate output signal, and a second input of the first photonic combiner is coupled to the second output of the second set of one or more cascading photonic gates and configured to receive the second photonic output signal.

13. The photonic circuit of claim 9, wherein the second photonic gate comprises a first photonic combiner, a phase shifter and a second photonic combiner that is coupled to an output of the first photonic combiner and an output of the phase shifter, an output of the second photonic combiner coupled to the second output of the second set of one or more cascading photonic gates.

14. The photonic circuit of claim 13, wherein a first input of the first photonic combiner is coupled to the first output of the first set of one or more cascading photonic gates and configured to receive the first intermediate output signal, and a second input of the first photonic combiner is coupled to the first output of the second set of one or more cascading photonic gates and configured to receive the first photonic output signal.

15. The photonic circuit of claim 1, wherein the photonic circuit is part of a photonic register of a photonic processor, and the photonic circuit is configured to operate as a photonic D-type register.

16. A non-transitory computer-readable storage medium comprising stored instructions that, when executed by at least one processor, cause the at least one processor to execute operations comprised to:
instruct a first set of one or more cascading photonic gates of a photonic circuit to receive a first photonic input signal at a first input of a first set of one or more inputs and to receive a second photonic input signal at a second input of the first set of one or more inputs;
instruct the first set of one or more cascading photonic gates to generate, at a first output of a first set of one or more outputs, a first intermediate output signal based at least in part on the first photonic input signal and the second photonic input signal;
instruct the first set of one or more cascading photonic gates to generate, at a second output of the first set of one or more outputs, a second intermediate output signal based at least in part on the first intermediate output signal and the second photonic input signal;
instruct a second set of one or more cascading photonic gates of the photonic circuit to receive the second intermediate output signal at a first input of a second set of one or more inputs coupled to the second output of the first set of one or more outputs, and to receive the first intermediate output signal at a second input of the second set of one or more inputs coupled to the first output of the first set of one or more outputs;
instruct the second set of one or more cascading photonic gates to generate, at a first output of a second set of one or more outputs, a first photonic output signal based at least in part on the second intermediate output signal and a second photonic output signal that was output by the second set of one or more cascading photonic gates at a second output of the second set of one or more outputs, and
instruct the second set of one or more cascading photonic gates to generate, at the second output of the second set of one or more outputs, the second photonic output signal based at least in part on the first intermediate output signal and the first photonic output signal.

17. The computer-readable storage medium of claim 16, wherein the stored instructions comprise further stored instructions that, when executed, cause the at least one processor to:
instruct the first set of one or more cascading photonic gates to receive, at the first input of the first set of one or more inputs, the first photonic input signal that comprises a first set of one or more multiplexed light signals of a set of one or more wavelengths;
instruct the first set of one or more cascading photonic gates to receive, at the second input of the first set of one or more inputs, the second photonic input signal that comprises a second set of one or more multiplexed light signals of the set of one or more wavelengths;
instruct the second set of one or more cascading photonic gates to output, at the first output of the second set of one or more outputs, the first photonic output signal that comprises a third set of one or more multiplexed light signals of the set of one or more wavelengths; and
instruct the second set of one or more cascading photonic gates to output, at the second output of the second set of one or more outputs, the second photonic output signal that comprises a fourth set of one or more multiplexed light signals of the set of one or more wavelengths.

18. The computer-readable storage medium of claim 16, wherein the stored instructions comprise further stored instructions that, when executed, cause the at least one processor to:
set a first amplitude value of a first bias signal that is input to a third input of the first set of one or more inputs, the first amplitude value being constant over time;
set a second amplitude value of a second bias signal that is input to a fourth input of the first set of one or more inputs, the second amplitude value being constant over time;
set a third amplitude value of a third bias signal that is input to a third input of the second set of one or more inputs, the third amplitude value being constant over time; and
set a fourth amplitude value of a fourth bias signal that is input to a fourth input of the second set of one or more inputs, the fourth amplitude value being constant over time.

19. The computer-readable storage medium of claim 16, wherein the stored instructions comprise further stored instructions that, when executed, cause the at least one processor to:
instruct an array of lasers to generate the first and second photonic input signals of a set of one or more wavelengths for input into the first and second inputs of the first set of one or more cascading photonic gates.

20. A method, comprising:
receiving a first photonic input signal at a first input of a first set of one or more inputs of a first set of one or more cascading photonic gates of a photonic circuit and a second photonic input signal at a second input of the first set of one or more inputs;
generating, by the first set of one or more cascading photonic gates, a first intermediate output signal at a first output of a first set of one or more outputs of the first set of one or more cascading photonic gates based at least in part on the first photonic input signal and the second photonic input signal;
generating, by the first set of one or more cascading photonic gates, a second intermediate output signal at a second output of the first set of one or more outputs based at least in part on the first intermediate output signal and the second photonic input signal;
receiving the first intermediate output signal at a second input of a second set of one or more inputs of a second set of one or more cascading photonic gates and the second intermediate output signal at a first input of the second set of one or more inputs coupled to the second output of the first set of one or more outputs;
generating, by the second set of one or more cascading photonic gates, a first photonic output signal at a first output of a second set of one or more outputs of the second set of one or more cascading photonic gates based at least in part on the second intermediate output signal and a second photonic output signal that was output by the second set of one or more cascading photonic gates at a second output of the second set of one or more outputs; and
generating, by the second set of one or more cascading photonic gates, the second photonic output signal at the second output of the second set of one or more outputs based at least in part on the first intermediate output signal and the first photonic output signal.
